(19) United States
(12) Patent Application Publication
(10) Pub. No.: US 2017/0081764 A1
(43) Pub. Date: Mar. 23, 2017

(54) SUBSTRATE PROCESSING APPARATUS

(71) Applicant: HITACHI KOKUSAI ELECTRIC INC., Tokyo (JP)

(72) Inventors: Yukinori ABURATANI, Toyama-shi (JP); Shun MATSUI, Toyama-shi (JP)

(73) Assignee: HITACHI KOKUSAI ELECTRIC INC., Tokyo (JP)

(21) Appl. No.: 15/255,352

(22) Filed: Sep. 2, 2016

(30) Foreign Application Priority Data
Sep. 17, 2015 (JP) 2015-184127

(51) Int. Cl. C23C 16/52; C23C 16/44; C23C 16/455

(52) U.S. Cl. CPC C23C 16/52; C23C 16/45523; C23C 16/4408; C23C 16/4557

(57) ABSTRACT

A substrate processing apparatus includes: a process chamber; a fluid supply unit supplying to the process chamber a fluid; a fluid supply pipe connecting the fluid supply unit to the process chamber; a first fluid discharge pipe connecting the process chamber to the fluid supply unit; a second fluid discharge pipe whereat a heat exchange unit is installed, the second fluid discharge pipe connecting the fluid supply unit to the fluid supply pipe; a flow path switching unit; and a control unit controlling the fluid supply unit and flow path switching unit to stop a supply of the fluid from the fluid supply pipe to the process chamber and supply the fluid from the fluid supply pipe to the heat exchange unit after the substrate is processed. The substrate processing apparatus suppresses temperature variation of fluid in the fluid supply unit depending on a situation of the process chamber.

### CROSS-REFERENCE TO RELATED PATENT APPLICATION

This non-provisional U.S. patent application claims priority under 35 U.S.C. §119 of Japanese Patent Application No. 2015-184127, filed on Sep. 17, 2015, the entire contents of which are hereby incorporated by reference.

### BACKGROUND

### 1. Field

The present disclosure relates to a substrate processing apparatus.

### 2. Description of the Related Art

When the flow rate of a fluid supplied to one process chamber among a plurality of chambers is changed, the heat balance of a constant temperature water tank in a fluid supply device (constant temperature water circulator) is changed, thereby varying the temperature of a fluid which is circulated after being supplied to another process chamber among the plurality of chamber. When the temperature variation of the fluid has effects on a process, the start of the process needs to be delayed until the temperature of the fluid is stabilized.

The temperature of the fluid within the fluid supply device is changed depending on the conditions of the process chambers.

### SUMMARY

Described herein is a technique capable of suppressing a temperature variation of a fluid in a fluid supply device, depending on a situation of a process chamber.

According to one aspect, a substrate processing apparatus may include: a process chamber where a substrate is processed; a fluid supply unit configured to supply to the process chamber a fluid at a predetermined temperature; a fluid supply pipe connecting the fluid supply unit to the process chamber to supply the fluid to the process chamber; a first fluid discharge pipe connecting the process chamber to the fluid supply unit to discharge the fluid to the fluid supply unit; a second fluid discharge pipe whereat a heat exchange unit is installed, the second fluid discharge pipe connecting the fluid supply unit to the fluid supply pipe to discharge the fluid to the fluid supply unit; a flow path switching unit disposed at a connecting portion of the fluid supply pipe and the second fluid discharge pipe; and a control unit configured to control the fluid supply unit and the flow path switching unit to stop a supply of the fluid from the fluid supply pipe to the process chamber and start a supply of the fluid from the fluid supply pipe to the heat exchange unit after the substrate is processed.

### BRIEF DESCRIPTION OF THE DRAWINGS

FIG. 1 is a schematic transverse cross-sectional view of the substrate processing system according to one embodiment described herein;

FIG. 2 is a longitudinal cross-sectional view of the substrate processing system according to the embodiment described herein;

FIG. 3 schematically illustrates a vacuum transfer robot of the substrate processing system according to the described herein;

FIG. 4 schematically illustrates a substrate processing apparatus according to the embodiment described herein;

FIG. 5 is a longitudinal cross-sectional view of a chamber according to the embodiment described herein;

FIG. 6 schematically illustrates a controller of the substrate processing system according to the embodiment described herein;

FIG. 7 is a flowchart of a substrate processing process according to the embodiment described herein;

FIG. 8 is a sequence diagram of the substrate processing process according to the embodiment described herein;

FIG. 9 schematically illustrates a general substrate processing system and a constant temperature water tank;

FIG. 10 schematically illustrates the substrate processing system and the constant temperature water tank according to the embodiment described herein;

FIG. 11 is a diagram illustrating the relation between heat exchange and flow rate in the substrate processing system and the constant temperature water tank according to the embodiment described herein;

FIG. 12 is a flowchart of a maintenance process according to the embodiment described herein;

FIG. 13 schematically illustrates a modification of the substrate processing system and the constant temperature water tank according to the embodiment described herein;

FIG. 14 schematically illustrates another modification of the substrate processing system and the constant temperature water tank according to the embodiment described herein; and

FIG. 15 schematically illustrates still another modification of the substrate processing system and the constant temperature water tank according to the embodiment described herein.

### DETAILED DESCRIPTION OF THE PREFERRED EMBODIMENTS

### First Embodiment

Hereafter, a first embodiment will be described with reference to the accompanying drawings.

Hereafter, a substrate processing system according to the first embodiment will be described.

(1) Configuration of Substrate Processing System

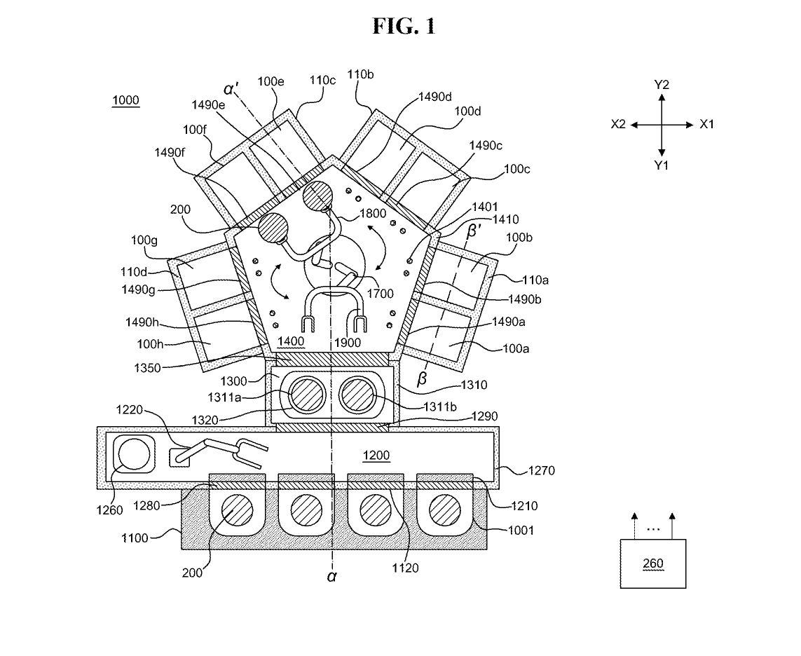

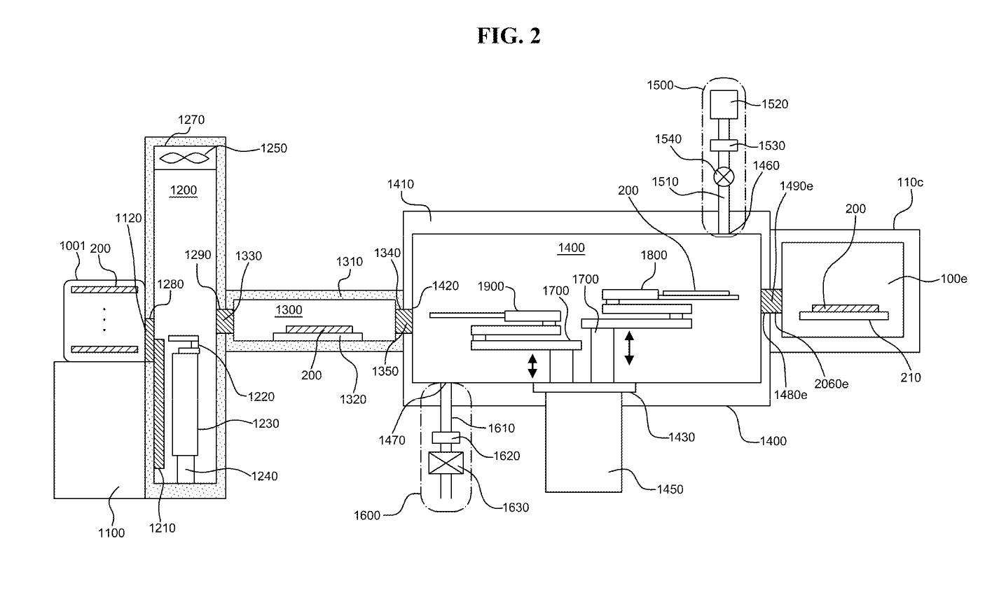

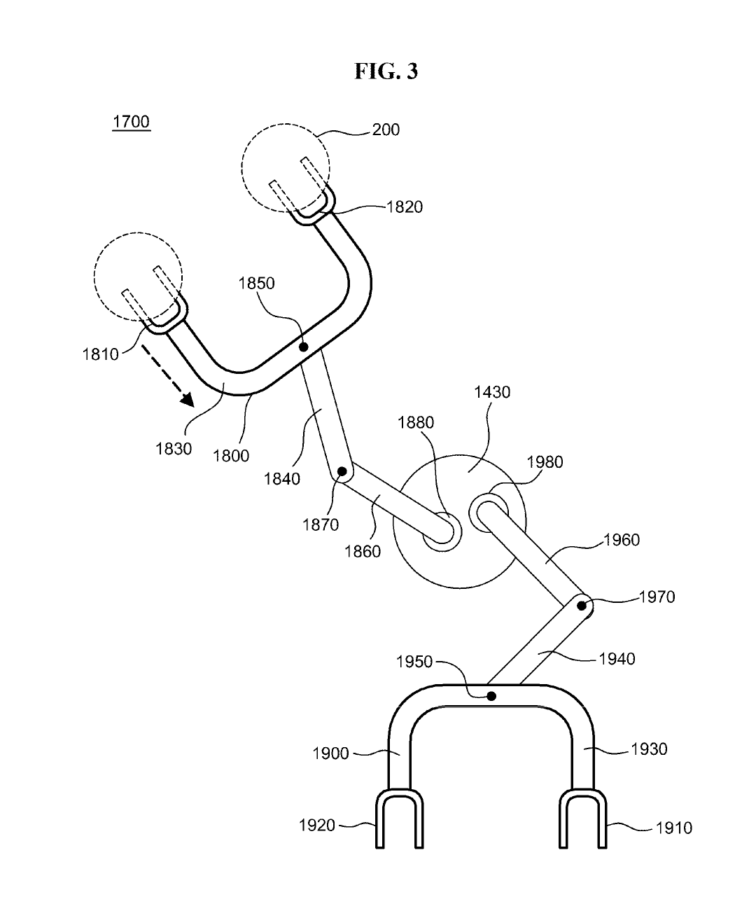

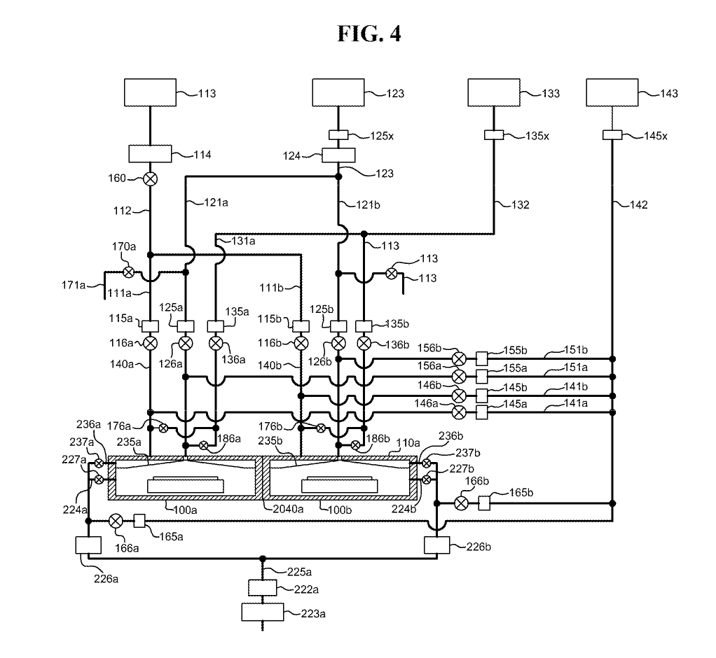

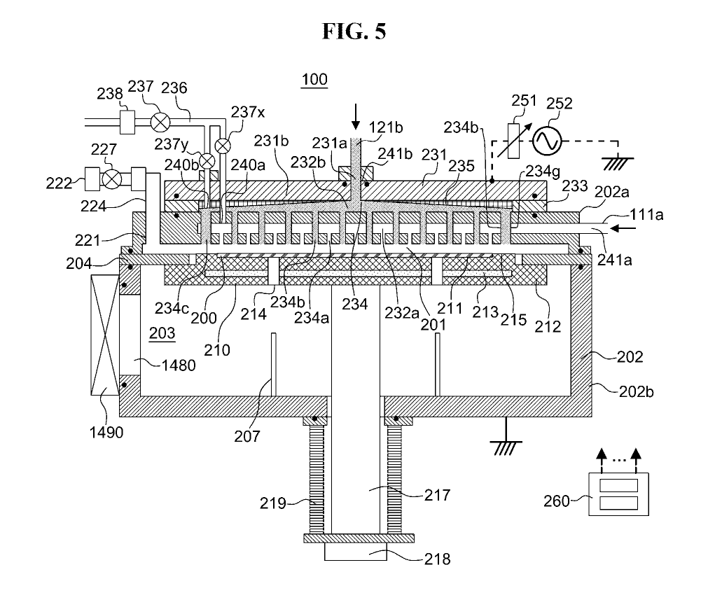

The substrate processing system according to the first embedment will be described with reference to FIGS. 1 to 4. FIG. 1 is a schematic transverse cross-sectional view of the substrate processing system according to the first embodiment. FIG. 2 is a longitudinal cross-sectional view of the substrate processing system according to the first embodiment, taken along the line α-α′ of FIG. 1. FIG. 3 is a diagram illustrating the detailed structure of an arm (vacuum transfer robot) of FIG. 1. FIG. 4 is a longitudinal cross-sectional view of a substrate processing apparatus according to the first embodiment, taken along the line β-β′ of FIG. 1. FIG. 4 illustrates a gas supply system for supplying a gas to a process module. FIG. 5 schematically illustrates a chamber installed in a process module.

Referring to FIGS. 1 and 2, the substrate processing system 1000 described herein is configured to process a wafer 200, and includes an IO stage 1100, an atmosphere transfer chamber 1200, a load lock chamber 1300, a vacuum transfer chamber 1400 and process modules 110a through 110d. Hereafter, the respective components of the substrate processing system 1000 will be described. In FIG. 1, X1 indicates the right side, X2 indicates the left side, Y1 indicates the front side, and Y2 indicates the rear side.

(Atmosphere Transfer Chamber and IO Stage)

The IO stage 1100 (loading port shelf) is installed at the front of the substrate processing system 1000. The IO stage 1100 has a plurality of pods 1001 placed thereon. Each of the pods 1001 is used as a carrier for transferring a substrate 200 such as a silicon (Si) substrate, and an unprocessed substrate (wafer) 200 or processed substrate 200 is horizontally stored in the pod 1001.

The pod 1001 has a cap 1120 installed thereon, and is opened/closed by a pod opener 1210 described below. The pod opener 1210 may open or close the cap 1120 of the pod 1001 placed on the IO stage 1100, and the substrate 200 may be loaded into the pod 1001 or unloaded out of the pod 1001 through a substrate loading/unloading port 1280. The pod 1001 is loaded on the IO stage 1100 or unloaded from the IO stage 1100 by an in-process transfer device RGV (not illustrated).

The IO stage 1100 is disposed adjacent to the atmosphere transfer chamber 1200. The load lock chamber 1300 described later is connected to a surface different from the surface of the atmosphere transfer chamber 1200, to which the IO stage 1100 is connected.

The atmosphere transfer chamber 1200 has an atmosphere transfer robot 1220 installed therein, the atmosphere transfer robot 1220 serving as a first transfer robot for transferring the substrate 200. As illustrated in FIG. 2, the atmosphere transfer robot 1220 is lifted/lowered by an elevator 1230 installed in the atmosphere transfer chamber 1200, and moved in a side-to-side direction by a linear actuator 1240.

As illustrated in FIG. 2, a clean unit 1250 for supplying clean air is installed at the top of the atmosphere transfer chamber 1200. As illustrated in FIG. 1, a device 1260 for aligning a notch or orientation flat formed on the substrate 200 is installed at the left side of the atmosphere transfer chamber 1200. Hereafter, the device 1260 will be referred to as “pre-aligner”.

As illustrated in FIGS. 1 and 2, the pod opener 1210 and the substrate loading/unloading port 1280 for loading the substrate 200 into the atmosphere transfer chamber 1200 or unloading the substrate 200 from the atmosphere transfer chamber 1200 are installed at the front side of a housing 1270 of the atmosphere transfer chamber 1200. The IO stage 1100 (loading port shelf) is installed at the opposite side of the pod opener 1210, that is, outside the housing 1270, with the substrate loading/unloading port 1280 interposed therebetween.

At the rear side of the housing 1270 of the atmosphere transfer chamber 1200, a substrate loading/unloading port 1290 is installed to load the wafer 200 into the load lock chamber 1300 or unload the wafer 200 out of the load lock chamber 1300. The substrate loading/unloading port 1290 may be opened or closed by a gate valve 1330 described later, and the wafer 200 may be loaded into the load lock chamber 1300 or unloaded out of the load lock chamber 1300 through the substrate loading/unloading port 1290.

[Load Lock (L/L) Chamber]

The load lock chamber 1300 is disposed adjacent to the atmosphere transfer chamber 1200. The vacuum transfer chamber 1400 is disposed on a surface different from a surface at which the atmosphere transfer chamber 1200 is disposed, among surfaces included in a housing 1310 constituting the load lock chamber 1300. Since the inner pressure of the housing 1310 of the load lock chamber 1300 is varied depending on the inner pressures of the atmosphere transfer chamber 1200 and the vacuum transfer chamber 1400, the load lock chamber 1300 has a structure capable of withstanding a negative pressure.

The substrate loading/unloading port 1340 is installed at a side of the housing 1310, adjacent to the vacuum transfer chamber 1400. The substrate loading/unloading port 1340 may be opened or closed by a gate valve 1350, and the wafer 200 may be loaded into the vacuum transfer chamber 1400 or unloaded out of the vacuum transfer chamber 1400 through the substrate loading/unloading port 1340.

The load lock chamber 1300 has a substrate placing table 1320 installed therein, the substrate placing table 1320 including at least two placing surfaces 1311a and 1311b on which wafers 200 are placed. The distance between the substrate placing surfaces 1311a and 1311b is set according to a distance between fingers included in a vacuum transfer robot 1700 described later.

(Vacuum Transfer Chamber)

The substrate processing system 1000 includes the vacuum transfer chamber 1400 serving as a transfer chamber where the substrate 200 is transferred under a negative pressure. The vacuum transfer chamber 1400 includes a housing 1410 which has a pentagonal shape when seen from the top, and the load lock chamber 1300 and the process modules 110a through 110d for processing the substrate 200 are connected to the respective sides of the pentagon. The vacuum transfer robot 1700 serving as a second transfer robot which transfers the substrate 200 under a negative pressure is installed in substantially the central portion of the vacuum transfer chamber 1400 with a flange 1430 set to a base. While the pentagonal vacuum transfer chamber 140 is exemplified in the first embodiment, the vacuum transfer chamber 1400 may be polygonal such as rectangular or hexagonal.

The housing 1410 has a substrate loading/unloading port 1420 installed at a sidewall thereof adjacent to the load lock chamber 1300. The substrate loading/unloading port 1420 may be opened or closed by the gate valve 1350, and the wafer 200 may be loaded into the vacuum transfer chamber 1400 or unloaded out of the vacuum transfer chamber 1400 through the substrate loading/unloading port 1420.

As illustrated in FIG. 2, the vacuum transfer robot 1700 installed in the vacuum transfer chamber 1400 may be lifted/lowered by the elevator 1450, while the airtightness of the vacuum transfer chamber 1400 is maintained by the flange 1430. The detailed configuration of the vacuum transfer robot 1700 will be described later. The elevator 1450 may independently lift/lower two arms 1800 and 1900 included in the vacuum transfer robot 1700.

The housing 1410 has an inert gas supply hole 1460 installed at the ceiling thereof, the inert gas supply hole 1460 being used for supplying an inert gas into the housing 1410. In the inert gas supply hole 1460, an inert gas supply pipe 1510 is installed. An inert gas source 1520, an MFC (Mass Flow Controller) 1530 and a valve 1540 are sequentially installed at the inert gas supply pipe 1510 from the upstream side toward the downstream side of the inert gas supply pipe 1510, and thus control the amount of inert gas supplied into the housing 1410.

An inert gas supply unit 1500 of the vacuum transfer chamber 1400 includes the inert gas supply pipe 1510, the MFC 1530 and the valve 1540. The inert gas supply unit 1500 may further include the inert gas source 1520 and the inert gas supply hole 1460.

An exhaust hole 1470 for exhausting the atmosphere of the housing 1410 is installed at the bottom portion of the housing 1410. The exhaust hole 1470 is connected to an exhaust pipe 1610. An APC (Automatic Pressure Controller) 1620 serving as a pressure controller and a pump 1630 are sequentially installed at the exhaust pipe 1610 from the upstream side toward the downstream side of the exhaust pipe 1610.

A gas exhaust unit 1600 of the vacuum transfer chamber 1400 includes the exhaust pipe 1610 and the APC 1620. The gas exhaust unit 1600 may further include the pump 1630 and the exhaust hole 1470.

The atmosphere of the vacuum transfer chamber 1400 is controlled by the cooperation between the inert gas supply unit 1500 and the gas exhaust unit 1600. For example, the inner pressure of the housing 1410 is controlled.

As illustrated in FIG. 1, the process modules 110a through 110d for processing the wafer 200 are connected to sidewalls at which the load lock chamber 130 is not installed, respectively, among the five sidewalls of the housing 1410.

A chamber 100 which is one of the components of the substrate processing apparatus is installed in each of the process modules 110a through 110d. Specifically, the process module 110a has chambers 100a and 100b installed therein. The process module 110b has chambers 100c and 100d installed therein. The process module 110c has chambers 100e and 100f installed therein. The process module 110d has chambers 100g and 100h installed therein.

Among the sidewalls of the housing 1410, the sidewalls facing the respective chambers 100 have a substrate loading/unloading port installed therein. For example, as illustrated in FIG. 2, a substrate loading/unloading port 1480e is installed in the sidewall facing the chamber 100e.

Similarly, in the case of the chamber 100a illustrated in FIG. 1, a substrate loading/unloading port is installed in the sidewall facing the chamber 100a.

Similarly, in the case of the chamber 100f illustrated in FIG. 1, a substrate loading/unloading port is installed in the sidewall facing the chamber 100f.

As illustrated in FIG. 1, gate valves 1490a through 1490h are installed in the chambers 100a through 100h, respectively. Specifically, the gate valve 1490a is installed between the chamber 100a and the vacuum transfer chamber 1400, and the gate valve 1490b is installed between the chamber 100b and the vacuum transfer chamber 1400. The gate valve 1490c is installed between the chamber 100c and the vacuum transfer chamber 1400, and the gate valve 1490d is installed between the chamber 100d and the vacuum transfer chamber 1400. The gate valve 1490e is installed between the chamber 100e and the vacuum transfer chamber 1400, and the gate valve 1490f is installed between the chamber 100f and the vacuum transfer chamber 1400. The gate valve 1490g is installed between the chamber 100g and the vacuum transfer chamber 1400, and the gate valve 1490h is installed between the chamber 100h and the vacuum transfer chamber 1400.

The substrate loading/unloading ports may be opened or closed by the respective gate valves 1490a through 1490h, and the wafer 200 may be loaded into the chambers 100a through 100h or unloaded out of the chambers 100a through 100h through the substrate loading/unloading ports.

Next, the vacuum transfer robot 1700 mounted in the vacuum transfer chamber 1400 will be described with reference to FIG. 3. FIG. 3 is an expanded view of the vacuum transfer robot 1700 of FIG. 1.

The vacuum transfer robot 1700 includes two arms 1800 and 1900. The arm 1800 includes a fork portion 1830 having two end effectors 1810 and 1820 installed at the front end thereof. The arm 1800 further includes a middle portion 1840 connected to the fork portion 1830 through a shaft 1850.

The wafers 200 unloaded from each of the process modules 110a through 110d are placed on the end effectors 1810 and 1820. FIG. 2 exemplifies placing the wafer 200 transferred out of the process module 110c.

The arm 1800 further includes a bottom portion 1860 connected to a location of the middle portion 1840 through a shaft 1870, the location of the middle portion 1840 being different from the location to which the fork portion 1830 is connected. The bottom portion 1860 is installed on the flange 1430 with a shaft 1880 interposed therebetween.

The arm 1900 includes a fork portion 1930 having two end effectors 1910 and 1920 installed at the front end thereof. The arm 1900 further includes a middle portion 1940 connected to the fork portion 1930 through a shaft 1950.

The wafers 200 unloaded out of the load lock chamber 1300 are placed on the end effectors 1910 and 1920.

The arm 1900 further includes a bottom portion 1960 connected to a location of the middle portion 1940 through a shaft 1970, the location of the middle portion 1940 being different from the location to which the fork portion 1930 is connected. The bottom portion 1960 is installed on the flange 1430 with a shaft 1980 interposed therebetween.

The end effectors 1810 and 1820 are disposed at higher positions than the end effectors 1910 and 1920.

The vacuum transfer robot 1700 may rotate around the shaft or extend the arms 1800 and 1900.

(Process Module)

Hereafter, the process module 110a among the process modules 110a through 110d will be exemplified. The process module 110a will be described with reference to FIGS. 1, 2 and 4. FIG. 4 illustrates the process module 110a, a gas supply unit connected to the process module 110a, and a gas exhaust unit connected to the process module 110a.

Although the process module 110a is exemplified herein, the other process modules 110b through 110d are configured in the same manner. Therefore, the descriptions of the other process modules 110b and 110d are omitted herein.

As illustrated in FIG. 4, the chambers 100a and 100b constituting the substrate processing apparatus for processing a wafer 200 are installed in the process module 110a. Between the chamber 100a and 100b, a partition wall 2040a is installed to prevent the inner atmospheres thereof from being mixed.

As illustrated in FIG. 2, a substrate loading/unloading port 2060e is installed at the contact portion between a sidewall of the chamber 100e and a sidewall of the vacuum transfer chamber 1400. Similarly, a substrate loading/unloading port is installed at the contact portion between a sidewall of the chamber 100a and a sidewall of the vacuum transfer chamber 1400.

Each of the chambers 100a through 100h has a substrate support 210 installed therein, the substrate support 210 supporting the wafer 200.

The gas supply unit for supplying a process gas to the chambers 100a and 100b is connected to the process module 110a. The gas supply unit includes a first gas supply unit (process gas supply unit), a second gas supply unit (reactive gas supply unit), a third gas supply unit (first purge gas supply unit) and a fourth gas supply unit (second purge gas supply unit). Hereafter, the first to fourth gas supply units will be described.

(First Gas Supply Unit)

As illustrated in FIG. 4, a buffer tank 114, MFCs 115a and 115b and process chamber-side valves 116a and 116b are installed between a process gas source 113 and the process module 110a. The process gas source 113 and the process module 110a are connected to a process gas common pipe 112 or process gas supply pipes 111a and 111b which are also referred to as a first gas supply pipe. The first gas supply unit includes the process gas common pipe 112, the MFCs 115a and 115b, the process chamber-side valves 116a and 116b and the process gas supply pipes 111a and 111b. The first gas supply unit may further include the process gas source 113. As the number of process modules installed in the substrate processing system is increased/decreased, the numbers of buffer tanks 114, MFCs 115a and 115b, process chamber-side valves 116a and 116b, process gas common pipes 112 and process gas supply pipes 111a and 111b, which are installed in the substrate processing system, may be increased/decreased.

At this time, the MFC may include a flow rate control device constituted by a combination of a mass flow meter and a flow rate controller or a flow rate control device such as a needle valve or orifice. MFCs described later may be configured in the same manner. When the MFC includes a flow rate control device such as a needle valve or orifice, it becomes easy to switch the gas supply at high speed.

(Second Gas Supply Unit)

As illustrated in FIG. 4, an RPU (Remote Plasma Unit) 124 serving as an activating unit, MFCs 125a and 125b and process chamber-side valves 126a and 126b are installed between a reactive gas source 123 and the process module 110a. The reactive gas source 123 and the process module 110a are connected to a reactive gas common pipe 122 and reactive gas supply pipes 121a and 121b which are referred to as a second gas supply pipe. The second gas supply unit includes the RPU 124, the MFCs 125a and 125b, the process chamber-side valves 126a and 126b, the reactive gas common pipe 122 and the reactive gas supply pipes 121a and 121b. The second gas supply unit may further include the reactive gas source 123. As the number of process modules installed in the substrate processing system is increased/decreased, the numbers of RPUs 124, MFCs 125a and 125b, process chamber-side valves 126a and 116b, reactive gas common pipes 122 and reactive gas supply pipes 121a and 121b, which are installed in the substrate processing apparatus, may be increased/decreased.

Vent lines 171a and 171b and vent valves 170a and 170b may be installed at the front of the process chamber-side valves 126a and 126b, and the reactive gas may be exhausted through the vent lines 171a and 171b and the vent valves 170a and 170b. As the vent lines 171a and 171b are installed, a deactivated reactive gas or low-activity reactive gas may not be supplied to the process chamber, but discharged through the vent lines 171a and 171b.

[Third Gas Supply Unit (First Purge Gas Supply Unit)]

As illustrated in FIG. 4, MFCs 135a and 135b, process chamber-side valves 136a and 136b and valves 176a, 176b, 186a and 186b are installed between a first purge gas source (first inert gas source) 133 and the process module 110a. The first purge gas source (first inert gas source) 133 and the process module 110a are connected to a purge gas (inert gas) common pipe 132 and purge gas (inert gas) supply pipes 131a and 131b. The third gas supply unit includes the MFCs 135a and 135b, the process chamber-side valves 136a and 136b, the valves 176a, 176b, 186a and 186b, the inert gas common pipe 132 and the inert gas supply pipes 131a and 131b. The third gas supply unit may further include the first purge gas source (first inert gas source) 133. As the number of process modules installed in the substrate processing system is increased/decreased, the numbers of MFCs 135a and 135b, process chamber-side valves 136a and 136b, valves 176a, 176b, 186a and 186b, inert gas common pipes 132 and inert gas supply pipes 131a and 131b, which are installed in the substrate processing system, may be increased/decreased.

[Fourth Gas Supply Unit (Second Purge Gas Supply Unit)]

As illustrated in FIG. 4, the fourth gas supply unit is configured to supply an inert gas to the process modules 110a and 110b through the process gas supply pipes 111a and 111b and the reactive gas supply pipes 121a and 121b. Second purge gas supply pipes 141a, 141b, 151a and 151b, MFCs 145a, 145b, 155a and 155b, and valves 146a, 146b, 156a and 156b are installed between a second purge gas source (second inert gas source) 143 and the process gas supply pipes 111a and 111b and the reactive gas supply pipes 121a and 121b. The fourth gas supply unit (second purge gas supply unit) includes the second purge gas supply pipes 141a, 141b, 151a and 151b, the MFCs 145a, 145b, 155a and 155b, and the valves 146a, 146b, 156a and 156b. In the first embodiment, the third and fourth gas supply units include separate gas sources (first and second purge gas sources). However, the third and fourth gas supply units may share one purge gas source.

The gas exhaust unit for exhausting the inner atmosphere of the chamber 100a and the inner atmosphere of the chamber 100b is connected to the process module 110a. As illustrated in FIG. 4, an APC 222a, a common gas exhaust pipe 225a and process chamber exhaust pipes 224a and 224b are installed between an exhaust pump 223a and the chambers 100a and 100b. The gas exhaust unit includes the APC 222a, the common gas exhaust pipe 225a and the process chamber exhaust pipes 224a and 224b. FIG. 4 exemplifies exhausting the inner atmospheres of the chambers 100a and 100b through one exhaust pump 223a. The gas exhaust unit may further include conductance adjusting units 226a and 226b capable of adjusting exhaust conductances of the process chamber exhaust pipes 224a and 224b. The gas exhaust unit may further include the exhaust pump 223a.

Next, the chamber 100 according to the first embodiment will be described. As illustrated in FIG. 5, the chamber 100 is part of a sheet-type substrate processing apparatus. A process of manufacturing a semiconductor device is performed by the chamber 100. The chambers 100a through 100h have the same configuration as illustrated in FIG. 5. Hereafter, the chamber 100a will be exemplified.

As illustrated in FIG. 5, the chamber 100 includes a process container 202. The process container 202 has a circular cross-sectional surface, and is a flat airtight container. The process container 202 is formed of quartz or a metallic material such as aluminum (Al) or stainless steel (SUS). The process container 202 includes a transfer space 203 and a process space 201 in which a wafer 200 such as a silicon substrate is processed. The process space 201 is also referred to as a process chamber. The process container 202 includes an upper container 202a and a lower container 202b. A partition plate 204 is installed between the upper container 202a and the lower container 202b. The space above the partition plate 204 surrounded by the upper container 202a is referred to as the process space 201, and the space under the partition plate 204 surrounded by the lower container 202b is referred to as the transfer space 203.

The lower container 202b has a substrate loading/unloading port installed at a side thereof, the substrate loading/unloading port being disposed adjacent to a gate valve, for example, a gate valve 1490a. The wafer 200 is moved between the vacuum transfer chamber 1400 and the transfer space 203 through the substrate loading/unloading port. The lower container 202b has lift pins 207 installed on the bottom portion thereof. The lower container 202b is grounded.

The substrate support 210 for supporting the wafer 200 is installed in the process chamber 201. The substrate support 210 includes a substrate placing table 212 having a substrate placing surface 211 on which the wafer 200 is placed. A heater 213 serving as a heating unit may be installed in the substrate support 210. As the heater 213 heats the substrate 200, the quality of a film formed on the wafer 200 can be improved. The substrate placing table 212 includes through-holes 214 through which the lift pins 207 are passed, the through-holes 214 being installed at positions corresponding to the lift pins 207.

The substrate placing table 212 is supported by a shaft 217. The shaft 217 is passed through the bottom portion of the process container 202, and connected to an elevating mechanism 218 outside the container 202. The elevating mechanism 218 is operated to lift/lower the shaft 217 and the substrate placing table 212. As the shaft 217 and the substrate placing table 212 are lifted/lowered, the wafer 200 placed on the substrate placing surface 211 is lifted/lowered. The lower portion of the shaft 217 is covered by a bellows 219. The inside of the process chamber 201 is sealed.

When the wafer 200 is transferred, the substrate placing table 212 is lowered until the substrate placing surface 211 of the substrate placing table 212 reaches a position (wafer transfer position) of the substrate loading/unloading port. When the wafer 200 is processed, the substrate placing table 212 is lifted until the wafer 200 placed on the substrate placing surface 211 reaches a position (wafer process position) in the process chamber 201 as illustrated in FIG. 5.

Specifically, when the substrate placing table 212 is lowered until the substrate placing table 212 reaches the substrate transfer position, the upper ends of the lift pins 207 protrude from the substrate placing surface 211, and the lift pins 207 support the wafer 200 from thereunder. When the substrate placing table 212 is lifted until the substrate placing table 212 reaches the wafer process position, the lift pins 207 are buried from the substrate placing surface 211, and the substrate placing surface 211 supports the wafer 200 from thereunder. Since the lift pins 207 are in direct contact with the wafer 200, the lift pins 207 may be formed of a material such as quartz or alumina. An elevating mechanism (not illustrated) may be installed at the lift pins 207. The substrate placing table 212 may be moved by the elevating mechanism 218 and the lift pins 207 may be moved by the elevating mechanism (not illustrated).

(Exhaust Unit)

An exhaust port 221 constituting a first exhaust unit for exhausting the atmosphere of the process chamber 201 is installed in the inner wall of the process chamber 201 (upper container 202a). A process chamber exhaust pipe 224 is connected to the exhaust port 221, and a valve 227 is installed at the process chamber exhaust pipe 224. The first exhaust unit (also referred to as an exhaust line) includes the exhaust port 221 and the process chamber exhaust pipe 224. The first exhaust unit may further include the valve 227 and a vacuum pump (not illustrated).

(Gas Introduction Port)

A first gas introduction port 241a for supplying various gases into the process chamber 201 is installed at a side of the upper container 202a. A first gas supply pipe 111a is connected to the first gas introduction port 241a. A second gas introduction port 241b for supplying various gases into the process chamber 201 is installed at the top (ceiling) of a shower head 234 installed at the top of the process chamber 201. A second gas supply pipe 121b is connected to the second gas introduction port 241b. The configuration of a gas supply unit connected to the first gas introduction port 241a serving as part of the first gas supply unit and the second gas introduction port 241b serving as part of the second gas supply unit will be described later. The first gas introduction port 241a through which a first gas is supplied may be installed at the top (ceiling) of the shower head 234. The first gas may be supplied through the center of a first buffer space 232a and the second gas introduction port 241b installed at the top of the shower head 234. As the first gas is supplied through the center of the first buffer space 232a, the first gas uniformly flows in the first buffer space 232a from the center of the first buffer space 232a toward the outer circumference, which makes it possible to uniformize the amount of gas supplied to the wafer 200.

(Gas Dispersion Unit)

The shower head 234 includes the first buffer space 232a, first dispersion holes 234a, a second buffer space 232b and second dispersion holes 234b. The shower head 234 is installed between the second gas introduction port 241b and the process chamber 201. The first gas introduced through the first gas introduction port 241a is supplied to the first buffer space 232a (first dispersion unit) of the shower head 234. The second gas introduction port 241b is connected to a lid 231 of the shower head 234, and a second gas introduced through the second gas introduction port 241b is supplied to the second buffer space 232b (second dispersion unit) of the shower head 234 through a hole 232a installed in the lid 231. The shower head 234 is formed of a material such as quartz, alumina, stainless steel or aluminum.

The lid 231 of the shower head 234 may be formed of a conductive metal. Thus, the lid 231 of the shower head 234 may serve as an activating unit (exciter) for exciting a gas existing in the first buffer space 232a, the second buffer space 232b or the process chamber 201. When the lid 231 of the shower head 234 serves as an activating unit, an insulating block 233 is installed between the lid 231 and the upper container 202a, and insulates the lid 231 from the upper container 202a. A matcher 251 and a high-frequency power supply 252 may be connected to the lid 231 (electrode) serving as an activating unit, and supply electromagnetic waves (high-frequency power or microwaves).

A gas guide 235 may be installed to guide the second gas supplied to the second buffer space 232b. The gas guide 235 has the hole 231a formed in the center thereof, and is cone-shaped with the diameter thereof increasing toward the outer circumference thereof. The lower end portion of the gas guide 235 is disposed outer than the outermost first dispersion hole 234a and the outermost second dispersion hole 234b.

A shower head exhaust port 240a constituting a first shower head exhaust unit for exhausting the atmosphere of the first buffer space 232a is installed in the upper portion of the inner wall of the first buffer space 232a. A shower head exhaust pipe 236 is connected to the shower head exhaust port 240a. A valve 237x and a valve 237 for controlling the inner pressure of the first buffer space 232a to a predetermined pressure are sequentially connected in series to the shower head exhaust pipe 236. The first shower head exhaust unit includes the shower head exhaust port 240a, the valve 237x and the shower head exhaust pipe 236.

A shower head exhaust port 240b constituting a second shower head exhaust unit for exhausting the atmosphere of the second buffer space 232b is installed at the upper surface of the inner wall of the second buffer space 232b. The shower head exhaust pipe 236 is connected to the shower head exhaust port 240b. A valve 237y and a valve 237 for controlling the inner pressure of the second buffer space 232b to a predetermined pressure are sequentially connected in series to the shower head exhaust pipe 236. The second shower head exhaust unit includes the shower head exhaust port 240b, the valve 237y and the shower head exhaust pipe 236.

Next, the relationship between the first buffer space 232a constituting the first gas supply unit and the second buffer space 232b constituting the second gas supply unit will be described. The first buffer space 232a communicates with the process chamber 201 through the first dispersion holes 234a. The second buffer space 232b communicates with the process chamber 201 through the second dispersion holes 234b. The second buffer space 232b is installed above the first buffer space 232a. As illustrated in FIG. 5, the second dispersion holes 234b (dispersion pipe) extending from the second buffer space 232b to the process chamber 201 penetrate the first buffer space 232a.

(Supply System)

The gas supply unit is connected to a gas introduction hole 241 connected to the lid 231 of the shower head 234. A process gas, a reactive gas and a purge gas are supplied through the gas supply unit.

(Control Unit)

As illustrated in FIG. 5, the chamber 100 includes a controller 260 for controlling the respective units of the chamber 100.

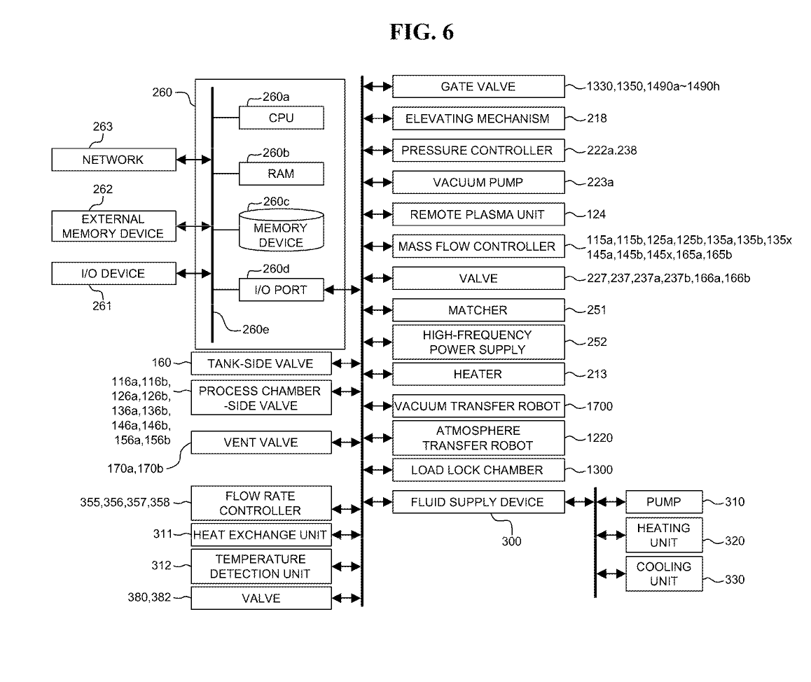

FIG. 6 is a diagram illustrating a schematic configuration of the controller 260. The controller 260 serving as a control unit is embodied by a computer including a CPU (Central Processing Unit) 260a, a RAM (Random Access Memory) 260b, a memory device 260c and an I/O port 260d. The RAM 260b, the memory device 260c and the I/O port 260d may exchange data with the CPU 260a through an internal bus 260e. An external memory device 262 or an I/O device 261 such as a touch panel may be connected to the controller 260.

The memory device 260c is embodied by a flash memory or HDD (Hard Disk Drive). A control program for controlling the operation of the substrate processing apparatus or a process recipe describing the sequence or condition of a substrate processing process described later is readably stored in the memory device 260c. The process recipe includes steps of the substrate processing process described later, which are combined to acquire a predetermined result through the controller 260, and functions as a program. Hereafter, the program recipe or control program is simply referred to as a program. In this specification, the term ‘program’ may indicate a program recipe, indicate a control program, or indicate both of the program recipe and the control program. The RAM 260b functions as a work area in which a program or data read by the CPU 260a is temporarily stored.

The I/O port 260d is connected to the gate valves 1330, 1350 and 1490a through 1490h, the elevating mechanism 218, the heater 213, the pressure controllers 222a and 238, the vacuum pump 223a, the matcher 251 and the high-frequency power supply 252. The I/O port 260d may be connected to the vacuum transfer robot 1700, the atmosphere transfer robot 1220, the load lock chamber 1300, the MFCs 115a, 115b, 125a, 125b, 125x, 135a, 135b, 135x, 145a, 145b, 145x, 155a, 155b, 165a and 165b, the valves 237e and 237f, the process chamber-side valves 116a, 116b, 126a, 126b, 136a, 136b, 176a, 176b, 186a and 186b, the tank-side valve 160, the vent valves 170a and 170b and the RPU 124.

The CPU 260a reads a control program from the memory device 260c and executes the read program. Furthermore, the CPU 260a reads a process recipe from the memory device 260c in response to an input of operation command from the I/O device 261. According to the contents of the read process recipe, the CPU 260a controls opening/closing operations of the gate valves 1330, 1350 and 1490a through 1490h, an elevating operation of the elevating mechanism 218, a power supply operation to the heater 213, pressure control operations of the pressure controllers 222a and 238, an on/off control operation of the vacuum pump 223a, a gas activation operation of the RPU 124, flow rate adjusting operations of the MFCs 115a, 115b, 125a, 125b, 135a and 135b, gas on/off control operations of the valves 237e and 237f, the process chamber-side valves 116a, 116b, 126a, 126b, 126c, 126d, 136a, 136b, 176a, 176b, 186a and 186b, the tank-side valve 160 and the vent valves 170a and 170b, and a power matching operation of the matcher 251, and an on/off control operation of the high-frequency power supply 252.

The controller 260 is not limited to a dedicated computer, but may be embodied by a universal computer. For example, an external memory device 262 storing the above-described program may be prepared, and a program may be installed in a universal computer through the external memory device 262, in order to embody the controller 260 according to the present embodiment. The external memory device 262 may include a magnetic disk such as a magnetic tape, flexible disk or hard disk, an optical disk such as CD or DVD, a magneto-optical disk such as MO, and a semiconductor memory such as a USB memory or memory card. The unit for supplying a program to the computer is not limited to the case in which the program is supplied through the external memory device 262. For example, the program may be supplied through a communication unit such as a network 263 (Internet or dedicated line), without the external memory device 262 interposed therebetween. The memory device 260c or the external memory device 262 may be embodied by a transitory computer readable recording medium. Hereafter, they are collectively referred to as recording media. In this specification, the term ‘recording medium’ may indicate the memory device 260c, indicate the external memory device 262, or indicate both of the memory device 260c and the external memory device 262.

(2) Substrate Processing Process

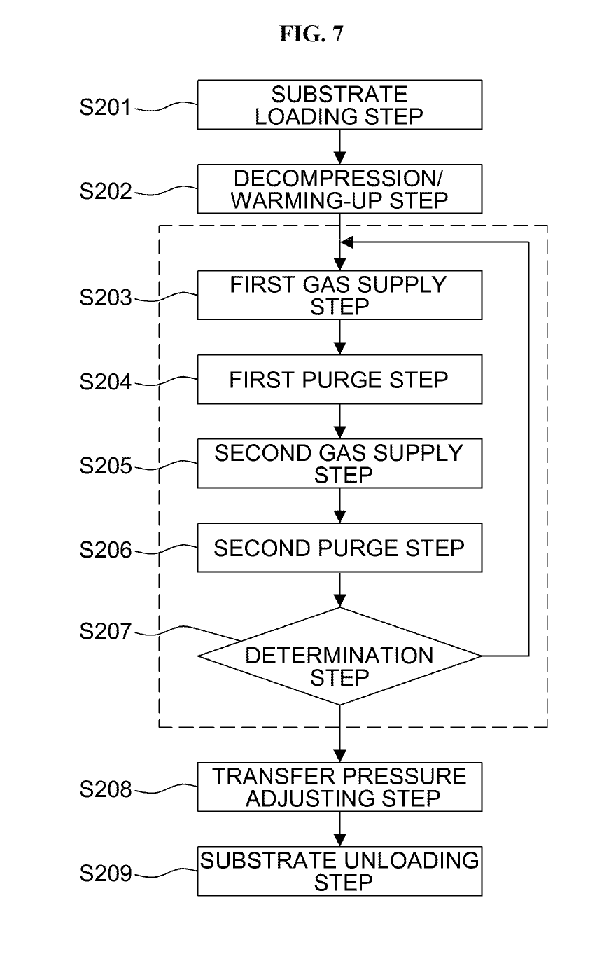

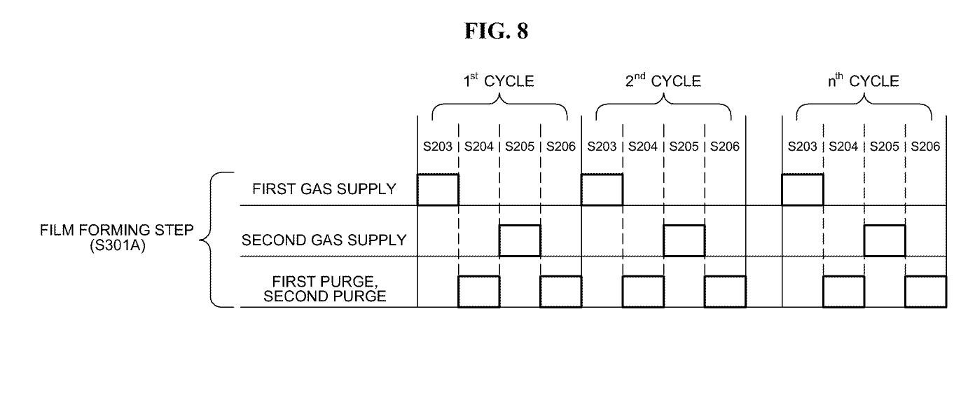

Referring to FIGS. 7 and 8, an example of the sequence in which a silicon oxide film (SiO film) is formed as an insulating film or silicon-containing film on a substrate will be described as an example of a process for manufacturing a semiconductor device using a process furnace of the substrate processing apparatus. In the following descriptions, the respective units constituting the substrate processing apparatus is controlled by the controller 260.

In this specification, “wafer” indicates “the wafer itself”, or indicates “a stacked body of the wafer and a predetermined film or layer formed thereon”. That is, the wafer and the predetermined layer or film formed on the surface of the substrate may be collectively referred to as the wafer. In this specification, “surface of substrate” indicates “the surface (exposed surface) of the wafer itself” or “the surface of a predetermined layer or film formed on the wafer, i.e. the uppermost surface of the wafer as a stacked body”.

Thus, when it is referred to as “supplying a predetermined gas to a wafer” in this specification, it may indicate that “the predetermined gas is directly supplied to the surface (exposed surface) of the wafer itself”, or indicate that “the predetermined gas is supplied onto a layer or film formed on the wafer, i.e. the uppermost surface of the wafer as a stacked body”. In this specification, when it is referred to as “forming a predetermined layer or film on a wafer”, it may indicate that “the predetermined layer or film is directly formed on the surface (exposed surface) of the wafer itself”, or indicate that “the predetermined layer (or film) is formed on a layer or film formed on the wafer, i.e. the uppermost surface of the wafer as a stacked body”.

Furthermore, when a term “substrate” is used in this specification, it may indicate the same case as a term “wafer” is used. In this case, the wafer in the above descriptions may be replaced with the substrate.

Hereafter, the substrate processing process will be described.

[Substrate Loading Step S201]

First, a wafer 200 is first loaded into the process chamber 201 at the substrate processing step. Specifically, the substrate support 210 is lowered by the elevating mechanism 218, and the lift pins 207 protrudes from the upper surface of the substrate support 210 through the through-holes 214. After the inner pressure of the process chamber 201 is adjusted to a predetermined pressure, the gate valve 1490 is opened. The wafer 200 is placed on the lift pins 207 through an opening of the gate valve 1490. After the wafer 200 is placed on the lift pins 207, the substrate support 210 is lifted to a predetermined position by the elevating mechanism 218, such that the wafer 200 is placed on the substrate support 210.

[Decompression/Warming-Up Step S202]

Next, the process chamber 201 is exhausted through the process chamber exhaust pipe 224 such that the inner pressure of the process chamber 201 is set to a predetermined degree of vacuum. At this time, the opening degree of the valve of the APC serving as a pressure controller 222a is feedback-controlled, based on a pressure value measured by a pressure sensor (not illustrated). Based on a temperature detected by a temperature sensor (not illustrated), the amount of power supplied to the heater 213 is feedback-controlled, such that the internal temperature of the process chamber 201 becomes a predetermined temperature. Specifically, the substrate support 210 is heated by the heater 213 in advance. When the temperature of the wafer 200 or the substrate support 210 is stabilized, the state is maintained for a predetermined time. When moisture or exhaust gas from a member remains in the process chamber 201, the moisture or exhaust gas may be removed by a vacuum exhaust operation or a purge operation through the supply of N₂ gas. In this way, the preparation before a film forming process is completed. When the process chamber 201 is exhausted to a predetermined pressure, the process chamber 201 may be exhausted to the degree of vacuum which can be reached at a time.

[Film Forming Step S301A]

Next, an example in which SiO layer is formed on the wafer 200 will be described. The film forming step S301A will be described in detail with reference to FIGS. 7 and 8.

After the wafer 200 is placed on the substrate support 210 and the atmosphere of the process chamber 201 is stabilized, steps S203 and S204 illustrated in FIGS. 7 and 8 are performed.

[First Gas Supply Step S203]

At the first supply step S203, an amino-silane-based gas serving as the first gas (raw material gas) is supplied to the process chamber 201 by the first gas supply unit. The amino-silane-based gas may include BDEAS (bis(diethylamino)silane) (H₂Si(NEt₂)₂). Specifically, when the gas valve 160 is opened, the amino-silane-based gas is supplied to the chamber 100 from a gas source. At this time, the process chamber-side valve 116a is opened, and the amino-silane-based gas is adjusted to a predetermined flow rate by the MFC 115a. The amino-silane-based gas of which the flow rate is adjusted is supplied to the decompressed process chamber 201 through the first buffer space 232a and the dispersion holes 234a of the shower head 234. As the process chamber 201 is continuously exhausted by the exhaust system, the inner pressure of the process chamber 201 is adjusted to a predetermined pressure. The amino-silane-based gas supplied to the wafer 200 is supplied to the process chamber 201, and has a pressure ranging from 100 Pa and 20,000 Pa, for example. In this way, the amino-silane-based gas is supplied to the wafer 200. By supplying the amino-silane-based gas, a silicon-containing layer is formed on the wafer 200.

[First Purge Step S204]

After the silicon-containing is formed on the wafer 200, the gas valve 116a of the first gas supply pipe 111a is closed to stop supplying the amino-silane-based gas. The first purge step S204 is performed by stopping the supply of the amino-silane-based gas (raw material gas) and exhausting the raw material gas existing in the process chamber 201 or the first buffer space 232a through the process chamber exhaust pipe 224.

At the first purge step S204, the residual gas may be discharged by not only simply vacuum-suctioning the residual gas, but also supplying an inert gas for extruding the residual gas. At the first purge step S204, the vacuum-suctioning and the supplying of an inert gas may be combined. At the first purge step S204, the vacuum-suctioning and the supplying of an inert gas may be alternately performed.

At this time, the valve 237 of the shower head exhaust pipe 236 may be opened to discharge the gas existing in the first buffer space 232a through the shower head exhaust pipe 236. During exhaust, the inner pressures (exhaust conductances) of the shower head exhaust pipe 236 and the first buffer space 232a are controlled by the valves 227 and 237. The valves 227 and 237 may be controlled such that the exhaust conductance of the shower head exhaust pipe 236 for exhausting the first buffer space 232a becomes higher than the exhaust conductance of the process chamber exhaust pipe 224 for exhausting the process chamber 201. The controlling of the valves 227 and 237 forms a gas flow from the first gas introduction port 241a corresponding to one end of the first buffer space 232a toward the shower head exhaust port 240a corresponding to the other end of the buffer space 232a. Thus, a gas adhering to the wall of the first buffer space 232a or a gas floating in the first buffer space 232a may not be introduced into the process chamber 201, but exhausted through the shower head exhaust pipe 236. The inner pressure of the first buffer space 232a and the pressure (exhaust conductance) of the process chamber 201 may be adjusted to suppress a gas backflow into the first buffer space 232a from the process chamber 201.

At the first purge step S204, the vacuum pump 223a is continuously operated to exhaust the gas existing in the process chamber 201 through the vacuum pump 223a. When the process chamber 201 is exhausted, the valves 227 and 237 may be controlled such that the exhaust conductance of the process chamber exhaust pipe 224 for exhausting the process chamber 201 becomes higher than the exhaust conductance of the shower head exhaust pipe 236 for exhausting the first buffer space 232a. The controlling of the valves 227 and 237 can form a gas flow toward the process chamber exhaust pipe 224 through the process chamber 201, thereby exhausting a gas remaining in the process chamber 201. By opening the valve 236a and supplying the inert gas with the flow rate thereof adjusted by the WC 135a, the inert gas can be reliably supplied onto the substrate, and a residual gas on the substrate can be efficiently removed.

After a predetermined has elapsed, the valve 136a is closed to stop supplying the inert gas, and the valve 237 is closed to block the flow path from the first buffer space 232a toward the shower head exhaust pipe 236.

More desirably, after the predetermined time has elapsed, the valve 237 may be closed while the vacuum pump 223a is continuously operated. Then, since a gas flow toward the process chamber exhaust pipe 224 through the process chamber 201 is not affected by the shower head exhaust pipe 236, the inert gas can be more reliably supplied onto the substrate, and a residual gas on the substrate can be more efficiently removed.

Purging the atmosphere of the process chamber indicates not only discharging a residual gas by simply vacuum-suctioning the residual gas, but also supplying an inert gas to extrude a residual gas. Thus, at the first purge step S204, a discharge operation may be performed by supplying an inert gas into the first buffer space 232a to extrude a residual gas. At the first purge step S204, the vacuum-suctioning and the supplying of the inert gas may be combined. At the first purge step S204, the vacuum-suctioning and the supplying of the inert gas may be alternately performed.

At this time, the flow rate of N₂ gas supplied to the process chamber 201 does not need to high, and the volume of the supplied N₂ gas may be equal to the volume of the process chamber 201, for example. As such, the purging operation can reduce the influence on the next step. As the process chamber 201 is not completely purged, the purge time can be shortened to improve the manufacturing throughput, and the consumption of N₂ gas can be minimized.

At this time, the temperature of the heater 213 may be set to the same temperature as the raw material gas is supplied onto the wafer 200. Specifically, the temperature of the heater 213 may range from 200° C. to 750° C., desirably from 300° C. to 600° C., or more desirably from 300° C. to 550° C. The flow rate of N₂ gas which is supplied as a purge gas through N₂ gas inert gas supply system ranges from 100 to 20,000 sccm, for example. In addition to N₂ gas, a rare gas such as Ar, He, Ne or Xe may be used as the purge gas.

[Second Gas Supply Step S205]

After the first purge step S204, the valve 126 is opened to supply an oxygen-containing gas as the second gas (reactive gas) to the process chamber 201 through the gas introduction port 241b, the second buffer space 232b and the dispersion holes 234b. The oxygen-containing gas may include one of oxygen gas (O₂), ozone gas (O₃), water (H₂O), nitrous oxide gas (N₂O) and combinations thereof. Hereafter, using O₂ gas will be exemplified. By supplying the second gas to the process chamber 201 through the second buffer space 232b and the dispersion holes 234b, the second gas may be uniformly supplied onto the substrate. Thus, the film thickness can be uniformized. The second gas activated through the RPU 124 serving as an activating unit (exciter) may be supplied into the process chamber 201.

At this time, the MFCs 125a and 125b adjust the flow rate of O₂ gas to a predetermined value. The flow rate of O₂ gas ranges from 100 sccm to 10,000 sccm, for example. The pressure controller 238 controls the inner pressure of the second buffer space 232b to a predetermined range. When O₂ gas passes through the RPU 124, the RPU 124 is in a power-on state, and activates (excites) O₂ gas.

When O₂ gas is supplied onto the silicon-containing layer formed on the wafer 200, the silicon-containing layer is modified. For example, a silicon element or a modified layer containing a silicon element is formed. By supplying O₂ gas activated by the RPU 124 onto the wafer 200, more modified layers may be formed.

The modified layer has a predetermined thickness, a predetermined distribution, and a predetermined penetration depth of oxygen element with respect to the silicon-containing layer, depending on the inner pressure of the process chamber 201, the flow rate of O₂ gas, the temperature of the wafer 200, and the power supply state of the RPU 124.

After the predetermined time has passed, the valve 126 is closed to stop supplying O₂ gas.

[Second Purge Step S206]

After the supply of O₂ gas is stopped, the second purge step S206 is performed by exhausting O₂ gas existing in the process chamber 201 or the second buffer space 232a through the first exhaust unit. The second purge step S206 is performed in the same manner as the first purge step S204 described above.

At the second purge step S206, the vacuum pump 223a is continuously operated to exhaust the gas existing in the process chamber 201 from the exhaust pipe 224. The valves 227 and 237 may be controlled such that the exhaust conductance of the process chamber exhaust pipe 224 for exhausting the process chamber 201 becomes higher than the exhaust conductance of the shower head exhaust pipe 236 for exhausting the second buffer space 232a. The controlling of the valves 227 and 237 can form a gas flow toward the process chamber exhaust pipe 224 through the process chamber 201, thereby exhausting the gas remaining in the process chamber 201. By opening the gas valve 136b and supplying an inert gas with the flow rate thereof adjusted by the WC 135b, the inert gas can be reliably supplied onto the substrate, thereby efficiently removing a residual gas on the substrate.

After a predetermined time has elapsed, the valve 136b is closed to stop supplying the inert gas, and the valve 237b is closed to block the buffer space 232b from the shower head exhaust pipe 236.

More desirably, after the predetermined time has elapsed, the valve 237b may be closed while the vacuum pump 223a is continuously operated. In this case, since a gas flow toward the process chamber exhaust pipe 224 through the process chamber 201 is not affected by the process chamber exhaust pipe 224, an inert gas can be more reliably supplied onto the substrate, thereby removing a residual gas more efficiently.

Purging the atmosphere of the process chamber indicates not only discharging a residual gas by simply vacuum-suctioning the residual gas, but also supplying an inert gas to extrude a residual gas. Thus, at the second purge step S206, a discharge operation may be performed by supplying an inert gas into the second buffer space 232b to extrude a residual gas. At the second purge step S206, the vacuum-suctioning and the supplying of an inert gas may be combined. At the second purge step S206, the vacuum-suctioning and the supplying of an inert gas may be alternately performed.

At this time, the flow rate of N₂ gas supplied to the process chamber 201 does not need to high, and the volume of the supplied N₂ gas may be equal to the volume of the process chamber 201, for example. As such, the purge operation can reduce the influence on the next step. As the process chamber 201 is not completely purged, the purge time can be shortened to improve the manufacturing throughput, and the consumption of N₂ gas can be minimized.

At this time, the temperature of the heater 213 may be set to the same temperature as the raw material gas is supplied onto the wafer 200. Specifically, the temperature of the heater 213 may range from 200° C. to 750° C., desirably from 300° C. to 600° C., or more desirably from 300° C. to 550° C. The flow rate of N₂ gas supplied as a purge gas through each inert gas supply system ranges from 100 to 20,000 sccm, for example. In addition to N₂ gas, a rare gas such as Ar, He, Ne or Xe may be used as the purge gas.

[Determination Step S207]

After the second purge step S206 is ended, the controller 260 determines whether the steps S203 through S206 of the film forming step S301A were performed a predetermined number of times (n times) where n is a natural number. That is, the controller 260 determines whether a desired thickness of film was formed on the wafer 200. By performing a cycle including the above-described steps S203 through S206 one or more times, an insulating film containing silicon and oxygen, that is, SiO film may be formed on the wafer 200. The above-described cycle may be performed a plurality of times. Thus, a predetermined thickness of SiO film is formed on the wafer 200.

When the cycle was not performed the predetermined number of times (No at step S207), the cycle of the steps S203 through S206 is repeated. When the cycle was performed the predetermined number of times (Y at step S207), the film forming step S301 is ended, and a transfer pressure adjusting step S208 and a substrate unloading step S209 are performed.

At the first gas supply step S203 or the second gas supply step S205, an inert gas may be supplied to the second buffer space 232b serving as the second dispersion unit when the first gas is supplied, or supplied to the first buffer space 232a serving as the first dispersion unit when the second gas is supplied. Then, the inert gas supplied to any one buffer space can be prevented from flowing into the other buffer space.

[Transfer Pressure Adjusting Step S208]

At the transfer pressure adjusting step S208, the process chamber 201 and the transfer space 203 are exhausted through the process chamber exhaust pipe 224 such that the inner pressure of the process chamber 201 or the transfer space 203 is set to a predetermined degree of vacuum. At this time, the inner pressure of the process chamber 201 or the transfer space 203 is adjusted to no less than the inner pressure of the vacuum transfer chamber 1400. During, before or after the transfer pressure adjusting step S208, the wafer 200 may be supported on the lift pins 207 such that the temperature of the wafer 200 falls to a predetermined temperature.

[Substrate Unloading Step S209]

After the inner pressure of the process chamber 201 is set to the predetermined degree of vacuum at the transfer pressure adjusting step S208, the gate valve 1490 is opened to unload the wafer 200 from the transfer space 203 into the vacuum transfer chamber 1400.

The wafer 200 is processed through the above-described steps S201 through S209. At least while the substrate is processed, a fluid is supplied to the process modules 110a through 110d from a fluid supply device serving as a fluid supply unit, and flows through the walls of the respective chambers 100a through 100h in the process modules 110a through 110d. A first fluid supply step is to supply a fluid from the fluid supply device to the chambers 100a through 100h. The fluid supply device includes a constant temperature water tank. The constant temperature tank is embodied by adding components such as thermometer, thermostat, heater and cooler to a tank for storing a material such as liquid, and constantly controls (adjusts) the temperature of a material such as liquid in the tank. The fluid includes a refrigerant or heating medium, and maintains the temperature of the inner walls of the chambers 100a through 100h at a predetermined temperature. In the following descriptions, a fluid serving as a refrigerant will be exemplified. The predetermined temperature ranges from 25° C. to 150° C., for example. In the following descriptions, maintaining the temperature of the inner walls of the chambers 100a through 110h at 50° C. will be exemplified. By installing a cooling pipe outside the inner walls of the chambers 100a through 100h and passing a fluid through the cooling pipe, the fluid may be supplied to the chambers 100a through 100h. As the fluid is passed through the cooling pipe, the chambers 100a through 100h can be cooled down.

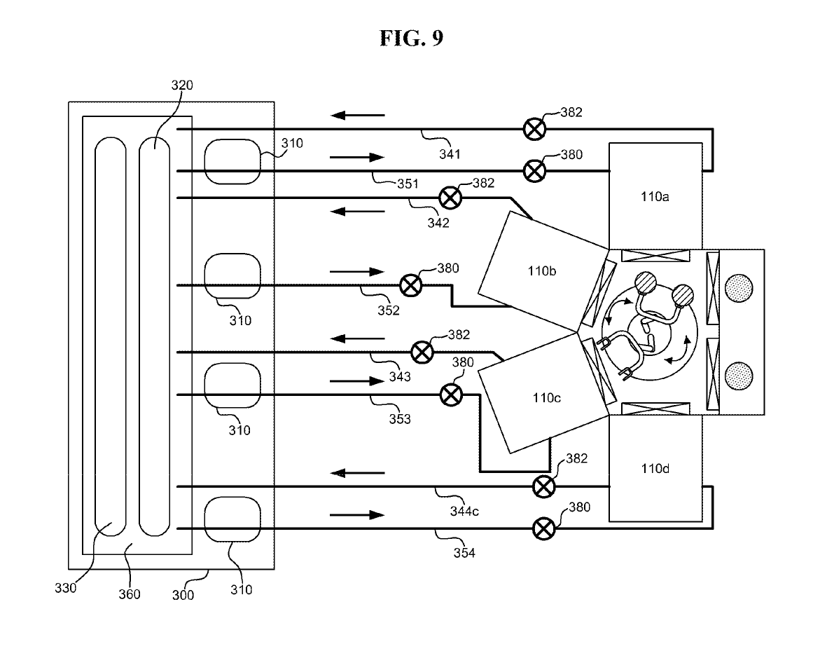

FIG. 9 is a diagram schematically illustrating a fluid flow between the fluid supply device 300 and the process modules 110a through 110d which are part of the substrate processing apparatus. The fluid supply device 300 includes a pump 310, a heating unit 320, a cooling unit 330 and a circulating tank 360. The same substrate processing process is performed in each of the process modules 110a through 110d. A fluid cooled to a predetermined temperature in the circulating tank 360 is supplied to the process module 110a through the pump 310 and a fluid supply pipe 351. The fluid warmed up by circulating through a portion such as the sidewall of the process module 110a is returned to the circulating tank 360 through a fluid discharge pipe 341. The fluid supply device 300 is connected to the controller 260, and the controller 260 may exchange information on the operation situation of the fluid supply device 300 with the fluid supply device 300. The valve 380 is installed to stop a flow of fluid in the fluid supply pipe 351, and the valve 382 is installed to stop a flow of fluid in the fluid discharge pipe 341.

Similarly, a fluid cooled to a predetermined temperature in the circulating tank 360 is supplied to the process modules 110b through 110d through pumps 310 and fluid supply pipes 352 through 354. The fluid warmed up by circulating through portions such as the sidewalls of the process modules 110b through 110d is returned to the circulating tank 360 through the fluid discharge pipes 342 through 344.

For example, when a maintenance process described later is performed in the process module 110d, a fluid does not flow through the fluid supply pipe 354 and the fluid discharge pipe 344, and is not supplied to the process module 110d. Before the maintenance process is performed in the process module 110d, four process modules 110a through 110d are cooled. However, when the maintenance process is performed in the process module 110d, three process modules 110a through 100c are cooled. When the number of cooled process modules is changed, the temperature of a fluid supplied from the circulating tank 360 or discharged from the circulating tank 360 is varied (the amount of heat is changed). When the temperature of the fluid is varied, it may have effects on the substrate processing process of each process module. For example, when the supply of a fluid to the process module 110d is stopped, the temperatures of the process modules 110a through 110c may fall. In order to suppress the temperature variation, the heating unit 320 or the cooling unit 330 in the circulating tank 360 needs to be controlled to adjust the temperature of the fluid supplied to the process modules 110a through 110c. Since it takes time to adjust the temperature of the fluid supplied to the process modules 110a through 110c, a waiting period occurs before the process is started. The lengths of the fluid supply pipes 351 through 354 and the fluid discharge pipes 341 through 344 which are installed between the fluid supply device 300 and the respective process modules 110a through 110d may differ depending on the process modules. In this case, the amounts of heat leaking to the outside or obtained from outside through the respective fluid supply pipes 351 through 354 may differ, and the temperature of the fluid supplied to the process modules 110a through 110d or the fluid supply device 300 may differ depending on the process modules. In this case, it is difficult to control the temperature of the fluid.

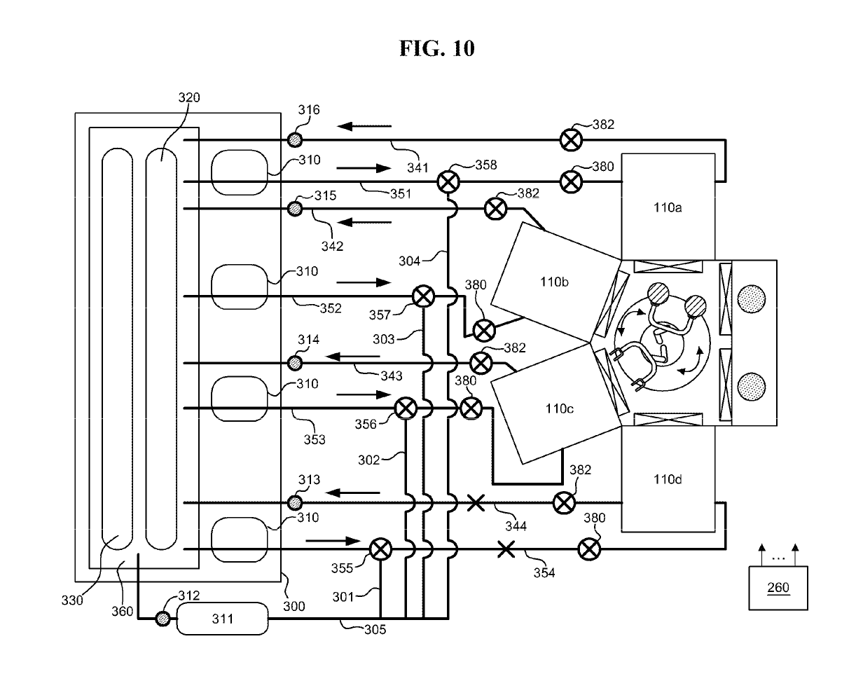

FIG. 10 is a diagram illustrating the first embodiment. In the first embodiment, suppose that a maintenance process is performed by the process module 110d. When the maintenance process is performed in the process module 110d, a fluid does not circulate through the process module 110d. Thus, a flow rate controller 355 (flow path switching unit) capable of switching between flow paths and controlling a flow rate is installed at the fluid supply pipe 354. A second fluid discharge pipe 301 is installed at the flow rate controller 355. The second fluid discharge pipe 301 is connected to a third fluid discharge pipe 305. A heat exchange unit 311 is installed at the fluid discharge pipe 305. A temperature detection unit 312 serving as a second temperature measuring unit is installed to detect the temperature of the fluid in the fluid discharge pipe 305. The fluid discharge pipe 305 is connected to the circulating tank 360 serving as a temperature control device. The controller 260 stores measurement data (temperature data) of the fluid, which a temperature detection unit 313 serving as a first temperature measuring unit detected before the maintenance process, controls the temperature detection unit 312 to detect the temperature of the fluid, and controls the heat exchange unit 311 such that the temperature of the fluid is equal to the fluid temperature before the maintenance process, thereby circulating the fluid at a predetermined temperature. The flow path switching unit 355, the heat exchange unit 311, the temperature detection unit 312 and the valves 380 and 382 may be connected to the controller 260, and the controller 260 may control the flow path switching unit 355, the heat exchange unit 311, the temperature detection unit 312 and the valves 380 and 382 according to an operation described later. The second and third fluid discharge pipes 301 and 305 do not need to be separately embodied, but integrated with each other. The heat exchange unit 311 may be installed at the second fluid discharge pipe 301.

By installing the second and third fluid discharge pipes 301 and 305 as bypass lines and performing a heat treatment through the heat exchange unit 311, the temperature of the fluid may be adjusted in the same manner as the fluid is simulatively passed to the process module 110d. Thus, the influence on the substrate processing process of the process modules 110a through 110c can be reduced without having effects on the temperature of the fluid flowing through the process modules 110a through 110c. As such, supplying a fluid from the fluid supply device 300 to the heat exchange unit 311 is referred to as a second fluid supply step.

As illustrated in FIG. 10, a flow rate controller 358 for the process module 110a is installed at the fluid supply pipe 351, in order to perform a maintenance process on each of the process modules 110a through 110c. A fluid discharge pipe 304 is installed at the flow rate controller 358. The fluid flows into the circulating tank 360 through the fluid discharge pipe 304, the fluid discharge pipe 305, the heat exchange unit 311 and the temperature detection unit 312. A flow rate controller 357 for the process module 110b is installed at the fluid supply pipe 352. The fluid discharge pipe 303 is installed at the flow rate controller 357. The fluid flows into the circulating tank 360 through the fluid discharge pipe 303, the fluid discharge pipe 303, the heat exchange unit 311 and the temperature detection unit 312. Similarly, a flow rate controller 356 for the process module 110c is installed at the fluid supply pipe 353. The fluid discharge pipe 302 is installed at the flow rate controller 356. The fluid flows into the circulating tank 360 through the fluid discharge pipe 302, the fluid discharge pipe 305, the heat exchange unit 311 and the temperature detection unit 312. The flow rate controllers (switching units) 356 through 358 and the valves 380 and 383 installed at the pipes 341 through 344 and 351 through 354 are connected to the controller 260. The controller 260 may control the respective components according to an operation described later. The valves 380 installed at the upstream side of the process modules 110a through 110d and the valves 382 installed at the downstream side of the process modules 110a through 110d can be controlled to suppress a backflow of fluid.

The controller 260 controls the flow path switching unit 355 to slowly switch the flow paths, such that the sum of an amount of heat exchanged between the fluid and the chamber 100 of the substrate processing apparatus after the substrate processing process and an amount of heat exchanged between the fluid and the heat exchange unit 311 is equal to an amount of heat exchanged between the fluid and the chamber 100 during the substrate processing process. Such a control can suppress effects on the other chambers (process modules) until a maintenance process is started. When the sum of the heat amounts is larger or smaller, the other chambers are heated or cooled. Thus, the process uniformity for each substrate is degraded.

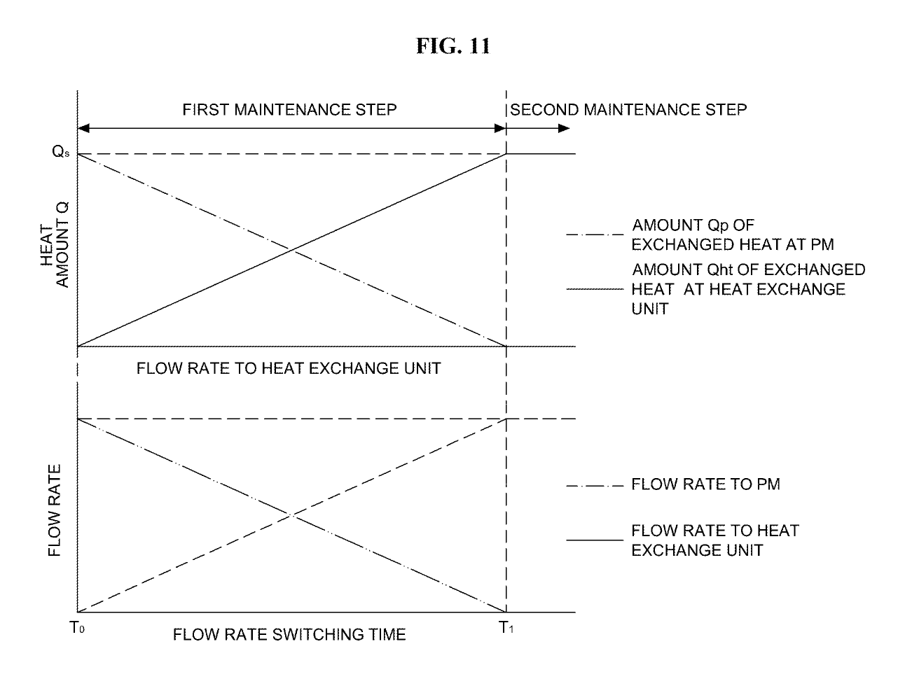

Desirably, the controller 260 controls the heat exchange unit 311 and the flow path switching unit 355 such that the relation between flow rate and heat amount is established as illustrated in FIG. 11. Specifically, the controller 260 controls the heat exchange unit 311 and the flow path switching unit 355 such that the sum of a heat amount Qp exchanged between the fluid and a process module PM and a heat amount Qht exchanged between the fluid and the heat exchange unit 311 is equal to the initial value Qs of the heat amount exchanged between the fluid and the process module PM. That is, the controller 260 controls the flow path switching unit 355 and the heat exchange unit 311 to satisfy a relation of Qp+Qht=Qs. An amount of heat may be represented by Q=MCΔT. At this time, Q[J] represents the amount of heat, M[g] represents the mass of the fluid, C[J/g·° C.] represents the specific heat of the fluid, and ΔT[° C.] represents a temperature rise. In FIG. 11, a period of time (flow rate switching time) between a time t0 and a time t1 is an arbitrary period of time, and when Qht≈Qs, the flow paths need to be slowly switched.

Although the case in which the maintenance process is performed by the process module 110d has been described with reference to FIG. 10, the present embodiment is not limited thereto. For example, a maintenance process may also be performed in other process modules. For example, when a maintenance process is performed in the process modules 110d and 110c, the flow rate controllers 355 and 356 are controlled to switch the flow paths. At this time, the controller 260 controls the temperature of the heat exchange unit 311 such that an amount of heat received by the process modules 110d and 110c is equal to an amount of heat received by the fluid in the heat exchange unit 311. The controller 260 may control the flow rate controller 355 and 356 to slowly switch the flow paths.

(3) Maintenance Process

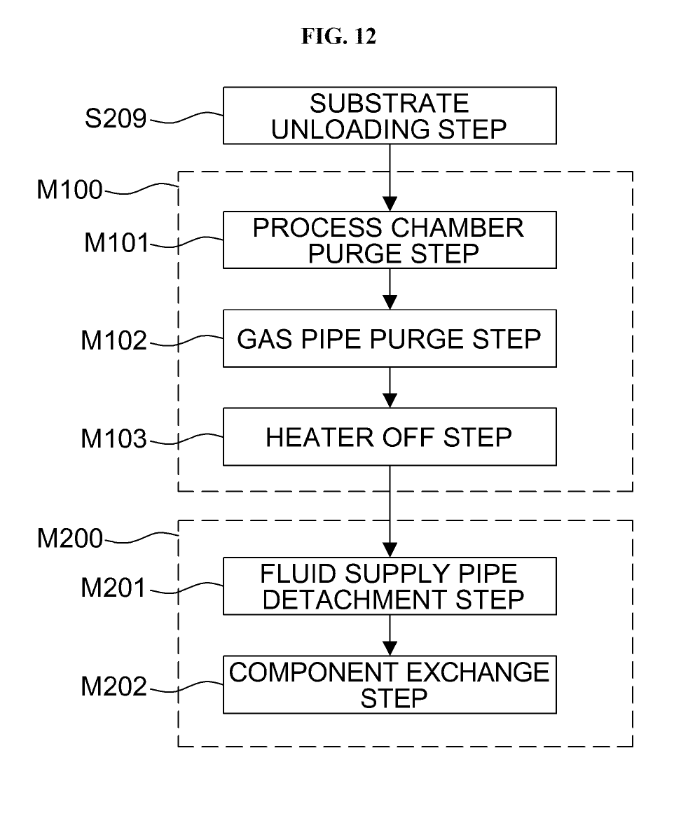

Next, a flow of the maintenance process will be described with reference to FIG. 12. In the following descriptions, the respective units constituting the substrate processing system is controlled by a component such as the controller 260.

As illustrated in FIG. 12, the maintenance process may include first and second maintenance processes M100 and M200.

[First Maintenance Step M100]

The first maintenance step M100 may be performed at the same time as the flow path switching operation of the flow path switching unit 355 as illustrated in FIG. 11, or performed before or after the flow path switching operation. The first maintenance step M100 includes at least one of a process chamber purge step M101, a gas pipe purge step M102 and a heater off step M103, which are described later.

[Process Chamber Purge Step M101]

At the process chamber purge step M101, any one or both of the atmospheres of the process chamber 201 and the transfer space 203 are exhausted and an inert gas is supplied, without the wafer 200 placed on the substrate support 210. After any one or both of the atmospheres of the process chamber 201 and the transfer space 203 are exhausted or purged by the inert gas, an inert gas is supplied until the inner pressures of the process chamber 201 and the transfer space 203 becomes a predetermined pressure.

[Gas Pipe Purge Step M102]

The gas pipe purge step M102 is performed before or after the process chamber purge step M101. The gas pipe purge step M102 may be performed at the same time as the process chamber purge step M101. At the gas pipe purge step M102, the inner atmosphere of a gas pipe connected to at least a process module in the gas supply system of FIG. 4 is exhausted. When the inner atmosphere of the gas pipe is exhausted, the inner atmosphere of the gas pipe may be extruded by supplying an inert gas to the gas pipe. The inner atmosphere of the gas exhaust unit as well as the gas supply system can be exhausted. When the inner atmosphere of the gas exhaust unit is exhausted, the inner atmosphere of the gas exhaust unit may be extruded by supplying an inert gas to the gas exhaust unit.

[Heater Off Step M103]

The heater off step M103 is performed after the gas pipe purge step M102. At the heater off step M103, the heater installed in the sheet-type substrate processing apparatus illustrated in FIG. 5 is turned off. For example, power supplied to the susceptor heater 213 is turned off to cool the susceptor heater 213. The susceptor is cooled to a temperature at which maintenance can be performed.

The first maintenance step M100 is performed as described above. The first maintenance step M100 may include other steps in addition to the process chamber purge step M101, the gas pipe purge step M102 and the heater off step M103, which are described above.

[Second Maintenance Step M200]

As illustrated in FIG. 12, the second maintenance step M200 is performed after the flow path switching unit 355 switches the flow paths, for example. The second maintenance step M200 includes any one or both of a fluid supply pipe detachment step M201 and a component exchange step M202.

[Fluid Supply Pipe Detachment Step M201]

At the fluid supply pipe detachment step M201, the fluid supply pipes 351 through 354 connected to the process module which is to be subjected to the second maintenance step M200 are detached. The fluid discharge pipes 341 through 344 connected to the process module which is to be subjected to the second maintenance step M200 are detached.

[Component Exchange Step M202]

At the component exchange step M202, a component included in the process module is exchanged. For example, the substrate support 210 is exchanged.

The second maintenance step M200 is performed as described above. The second maintenance step M200 may include other steps in addition to the fluid supply pipe detachment step M201 and the component exchange step M202, which are described above.

The above-described substrate processing process may be performed in a process module in which a maintenance process is not performed.

### Other Embodiments

In addition to the first embodiment described above, modifications described later may be used.

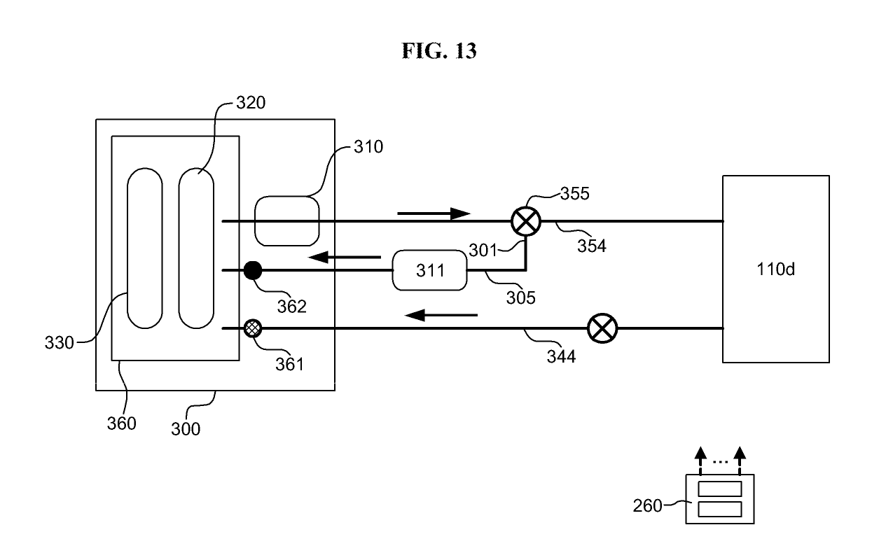

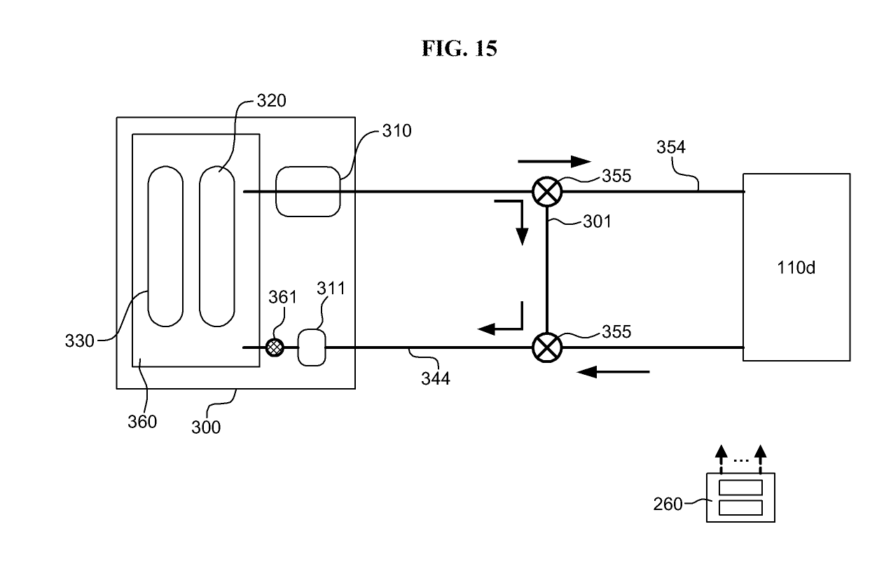

For example, the substrate processing apparatus (substrate processing system) illustrated in FIG. 10 may be modified as illustrated in FIG. 15. FIG. 13 illustrates only one process module of the substrate processing apparatus. A fluid flows from the circulating tank 360 of the fluid supply device 300 to the fluid discharge pipe 344. The fluid is supplied to the process module 110d through the fluid supply pipe 354. The fluid warmed up in the process module 110d is returned to the circulating tank 360 through the fluid discharge pipe 344. At this time, the temperature of the fluid is measured by a temperature sensor 361 installed on the fluid discharge pipe 344 at the circulating tank 360, and stored in a memory unit of the controller 260. During the maintenance of the process module 110d, a fluid is passed to the fluid discharge pipe 301 by the valve 355 (for example, a three way valve) which is a switching unit installed in the fluid supply pipe 354, and heated in the heat exchange unit 311 through the fluid discharge pipe 305. The heated fluid is returned to the circulating tank 360 through a temperature sensor 362. At this time, the exchange unit 311 is controlled such that the temperatures of the temperature sensor 361 and the temperature sensor 362 are equal to each other, the temperatures being stored in the controller 260. Such a control can stabilize the temperature of the circulating fluid without supplying a fluid to the process module 110d, during the maintenance of the process module 110d.

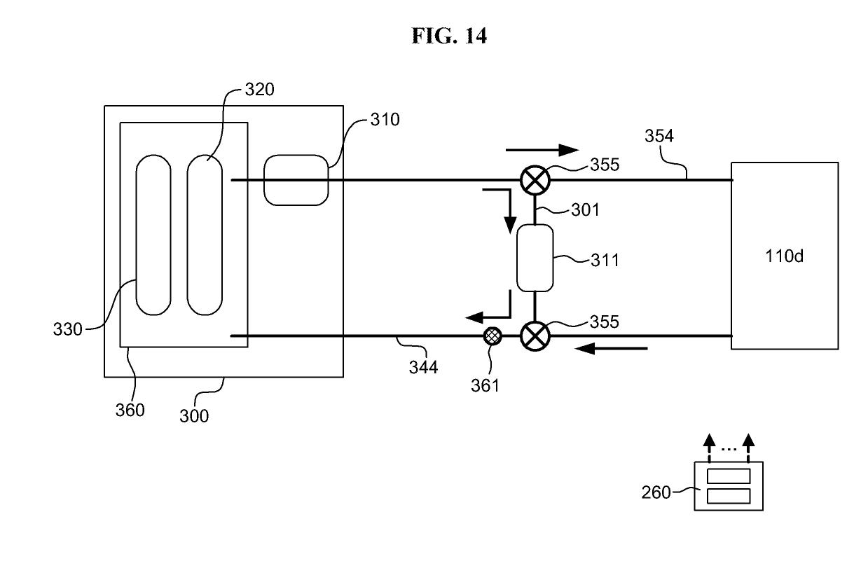

The substrate processing apparatus of FIG. 10 may be modified as illustrated in FIG. 14. FIG. 14 illustrates only one process module of the substrate processing apparatus. A fluid flows from the circulating tank 360 of the fluid supply device 300 to the fluid discharge pipe 344. The fluid is supplied to the process module 110d through the fluid supply pipe 354. The fluid is warmed up in the process module 110d, and returned to the circulating tank 360 through the fluid discharge pipe 344. At this time, the temperature of the fluid is measured by the temperature sensor 361 installed on the fluid discharge pipe 344 at the circulating tank 360, and stored in the memory unit of the controller 260. During the maintenance of the process module 110d, the fluid is passed to the fluid discharge pipe 301 by the valve 355 (for example, three way valve) which is a flow path switching unit installed at the fluid supply pipe 354. The fluid is heated in the heat exchange unit 311. The heated fluid is returned to the circulating tank 360 through the fluid discharge pipe 344 and the temperature sensor 361 by the valve 355 (for example, three-way valve) installed at the connection portion of the fluid discharge pipe 344. At this time, the exchange unit 311 is controlled such that the temperature of the temperature sensor 361 before maintenance and the temperature of the temperature sensor 361 after maintenance are equal to each other, the temperatures being stored in the controller 260. Such a configuration can stabilize the temperature of the circulating fluid without supplying a fluid to the process module 110d, during the maintenance of the process module 110d. Furthermore, the number of temperature sensors can be reduced without making the piping complex.

The controller 260 may control the flow path switching unit to slowly switch the flow paths, such that the sum of an amount of heat exchanged between the fluid and the chamber 100 and an amount of heat exchanged between the fluid and the heat exchange unit 311 after the substrate is processed is equal to an amount of heat exchanged between the fluid and the chamber 100 while the substrate is processed. Such a configuration can perform the maintenance of the process module without stopping the substrate processing apparatus, thereby reducing a downtime.

Even when the sum of the amount of heat exchanged between the fluid and the chamber 100 and the amount of heat exchanged between the fluid and the heat exchange unit 311 after the substrate is processed is different from the amount of heat exchanged between the fluid and the chamber 100 while the substrate is processed, the difference in heat amount can be reduced by the constant temperature water tank. A buffer for reducing the difference in heat amount may be installed in the constant temperature water tank.

As illustrated in FIGS. 13 and 14, when the maintenance is performed by the process modules, the temperature adjusting time of the heat exchange unit 311 or the switching time of the flow paths can be shortened by installing the heat exchange unit 311 in each of the process modules.

The substrate processing apparatus of FIG. 14 may be modified as illustrated in FIG. 15. The heat exchange unit 311 of FIG. 14 is installed on the fluid discharge pipe 301, but the heat exchange unit 311 of FIG. 15 may be installed at the front of the circulating tank 360. That is, the heat exchange unit 311 of FIG. 14 is installed outside the fluid supply device 300, but the heat exchange unit 311 of FIG. 15 may be installed in the fluid supply device 300. In the substrate processing apparatus illustrated in FIG. 15, the heat exchange unit 311 and the valves 355 serving as the flow path switching unit are controlled such that a temperature measured by the temperature sensor 361 before flow paths are switched by the valves 355 is equal to a temperature measured by the temperature sensor 361 after the flow paths are switched by the valves 355. The valve 355 may be controlled to slowly switch the flow paths. Even when the response to temperature in the heat exchange unit 311 is poor, the poor response can be compensated for by slowly switching the flow paths through the valves 355. When the rising speed of temperature in the heat exchange unit 311 is high, the switching speed of the flow paths may be lowered to return the fluid to the circulating tank 360 while the fluid has a predetermined amount of heat.

In the process module after the maintenance process, a step of switching flow paths which satisfy the relation of Qp+Qht=Qs in FIG. 11 may be performed. When the step of switching the flow paths is performed, the flow paths are switched such that the temperature of the process module rises from a maintenance temperature to a process temperature. Thus, it is possible to shorten the time required until the substrate processing process is started after the maintenance process is ended.

The curve illustrated in FIG. 11 is a simple proportional curve, but is not limited thereto. For example, the curve may be changed in a stepwise manner or changed in an exponential manner. Furthermore, the curve may have an arbitrary slope.

The above-described embodiments exemplify the methods of forming a film by alternately supplying a raw material gas and a reactive gas. However, when an amount of vapor-phase reaction or by-products between the raw material gas and the reactive gas falls within a permissible range, the above-described embodiments may be applied to other methods. The above-described embodiments may also be applied to a method in which the supply timings of the raw material gas and the reactive gas overlap each other.

The above-described embodiments exemplify a process of forming a film, but may be applied to other processes. The above-described embodiments may be applied to various processes such as a diffusion process, an oxidation process, a nitridation process, an oxy-nitridation process, a reduction process, an oxidation-reduction process, an etching process and a heating process. The embodiments described herein may also be applied when the surface of a substrate or a film formed on the substrate is subjected to a plasma oxidation process or plasma nitridation process using only a reactive gas. The embodiments described herein may also be applied to a plasma annealing process using only a reactive gas.

The above-described embodiments exemplify a process for manufacturing a semiconductor device, but may be applied to other processes as well as the process for manufacturing a semiconductor device. The embodiments described herein may be applied to a process for manufacturing a liquid crystal device, a process of manufacturing a solar battery, a process for manufacturing a light emitting device, and a substrate processing process such as a processing process of a glass substrate, a processing process of a ceramic substrate or a processing process of a conductive substrate.

The above-described embodiments exemplify forming a silicon oxide film using a silicon-containing gas and oxygen-containing gas as the raw material gas and the reactive gas, but may also be applied when a film is formed using other gases. The above-described embodiments may also be applied when an oxygen-containing film, a nitrogen-containing film, a carbon-containing film, a boron-containing film, a metal-containing film and combinations thereof are formed. That is, the above-described embodiments may also be applied when a film such as SiN film, AlO film, ZrO film, HfO film, HfAlO film, ZrAlO film, SiC film, SiCN film, SiBN film, TiN film, TiC film or TiAlC film is formed. In order to obtain the same effects as the above-described embodiments, the gas characteristics (adsorption, desorption and steam pressure) of a raw material gas and a reactive gas which are used to form the above-described films may be compared to properly change the supply positions or the structure of the shower head 234.

The number of changes installed in a process module may be one or more. When a plurality of chambers are installed in the process module, the thermal capacity of the process module is increased. Thus, when the maintenance for one or more process modules is performed, the influence by heat is increased.

The above-described embodiments exemplify an apparatus which processes one substrate in one process chamber, but are not limited thereto. The embodiments described herein may also be applied to an apparatus in which a plurality of substrates are arranged in the horizontal or vertical direction, for example.

The constant temperature water tank installed in the above-described fluid supply device may include a chiller or heater.

The above-described fluid may include a refrigerant, cooling water and heat transfer medium, for example. Specifically, water, Galden, gas (carbon dioxide, Freon, ammonia) and oil (silicon oil) may be used as the fluid.

The above-described flow path switching unit may include one or more of a three way valve, a ball valve, a needle valve, a hand valve and an LMFC (Liquid MFC) which are flow rate controllers.

The above-described embodiments exemplify cooling a heated process module, but are not limited thereto. For example, the above-described embodiments may be applied when a maintenance process is performed by heating a cooled process module to a predetermined temperature. The above-described embodiments may also be applied when a maintenance process is performed by controlling the flow path switching unit or the heat exchange unit to heat a cooled process module to a predetermined temperature.

The above-described embodiments exemplify the control from the substrate processing process to the maintenance process, but are not limited thereto. For example, the above-described embodiments may perform the same control even when the process is changed to a chamber basis or process module basis. Furthermore, the above-described embodiments may perform the same control even when the heater is turned off to a long-term idling state on a chamber basis or process module basis.

The technique described herein can suppress a variation in temperature of a fluid in the fluid supply device, depending on the situation of the process chamber.

What is claimed is:

1. A substrate processing apparatus comprising:
a process chamber where a substrate is processed;
a fluid supply unit configured to supply to the process chamber a fluid at a predetermined temperature;
a fluid supply pipe connecting the fluid supply unit to the process chamber to supply the fluid to the process chamber;
a first fluid discharge pipe connecting the process chamber to the fluid supply unit to discharge the fluid to the fluid supply unit;
a second fluid discharge pipe whereat a heat exchange unit is installed, the second fluid discharge pipe connecting the fluid supply unit to the fluid supply pipe to discharge the fluid to the fluid supply unit;
a flow path switching unit disposed at a connecting portion of the fluid supply pipe and the second fluid discharge pipe; and
a control unit configured to control the fluid supply unit and the flow path switching unit to stop a supply of the fluid from the fluid supply pipe to the process chamber and start a supply of the fluid from the fluid supply pipe to the heat exchange unit after the substrate is processed.

2. The substrate processing apparatus of claim 1, wherein the control unit is further configured to control the flow path switching unit to increase a flow rate of the fluid supplied from the fluid supply pipe to the heat exchange unit while decreasing a flow rate of the fluid supplied from the fluid supply pipe to the process chamber after the substrate is processed.

3. The substrate processing apparatus of claim 2, wherein the control unit is further configured to control the flow path switching unit such that a sum of the flow rate of the fluid supplied from the fluid supply pipe to the process chamber and the flow rate of the fluid supplied from the fluid supply pipe to the heat exchange unit after the substrate is processed is equal to a flow rate of the fluid supplied from the fluid supply unit to the process chamber while the substrate is processed in the process chamber.

4. The substrate processing apparatus of claim 2, wherein the control unit is further configured to control the flow path switching unit such that a sum of an amount of heat exchanged between the fluid and the process chamber and an amount of heat exchanged between the fluid and the heat exchange unit after the substrate is processed is equal to an amount of heat exchanged between the fluid and the process chamber while the substrate is processed in the process chamber.

5. The substrate processing apparatus of claim 3, wherein the control unit is further configured to control the flow path switching unit such that a sum of an amount of heat exchanged between the fluid and the process chamber and an amount of heat exchanged between the fluid and the heat exchange unit after the substrate is processed is equal to an amount of heat exchanged between the fluid and the process chamber while the substrate is processed in the process chamber.

6. The substrate processing apparatus of claim 1, further comprising:
a first temperature measuring unit installed at the first fluid discharge pipe; and
a second temperature measuring unit installed at the second fluid discharge pipe between the fluid supply unit and the heat exchange unit,
wherein the control unit is further configured to control the heat exchange unit and the flow path switching unit based on temperatures measured by the first temperature measuring unit and the second temperature measuring unit.

7. The substrate processing apparatus of claim 2, further comprising:
a first temperature measuring unit installed at the first fluid discharge pipe; and
a second temperature measuring unit installed at the second fluid discharge pipe between the fluid supply unit and the heat exchange unit,
wherein the control unit is further configured to control the heat exchange unit and the flow path switching unit based on temperatures measured by the first temperature measuring unit and the second temperature measuring unit.

8. The substrate processing apparatus of claim 3, further comprising:
a first temperature measuring unit installed at the first fluid discharge pipe; and
a second temperature measuring unit installed at the second fluid discharge pipe between the fluid supply unit and the heat exchange unit,
wherein the control unit is further configured to control the heat exchange unit and the flow path switching unit based on temperatures measured by the first temperature measuring unit and the second temperature measuring unit.

9. The substrate processing apparatus of claim 4, further comprising:
a first temperature measuring unit installed at the first fluid discharge pipe; and
a second temperature measuring unit installed at the second fluid discharge pipe between the fluid supply unit and the heat exchange unit,
wherein the control unit is further configured to control the heat exchange unit and the flow path switching unit based on temperatures of the fluid measured by the first temperature measuring unit and the second temperature measuring unit.

10. The substrate processing apparatus of claim 6, wherein the control unit is further configured to control the heat exchange unit such that a temperature of the fluid supplied from the fluid supply pipe to the process chamber measured by the first temperature measuring unit while the substrate is processed in the process chamber is equal to a temperature of the fluid supplied from the fluid supply pipe to the heat exchange unit after the substrate is processed.

11. The substrate processing apparatus of claim 7, wherein the control unit is further configured to control the heat exchange unit such that a temperature of the fluid supplied from the fluid supply pipe to the process chamber measured by the first temperature measuring unit while the substrate is processed in the process chamber is equal to a temperature of the fluid supplied from the fluid supply pipe to the heat exchange unit after the substrate is processed.

12. The substrate processing apparatus of claim 8, wherein the control unit is further configured to control the heat exchange unit such that a temperature of the fluid supplied from the fluid supply pipe to the process chamber measured by the first temperature measuring unit while the substrate is processed in the process chamber is equal to a temperature of the fluid supplied from the fluid supply pipe to the heat exchange unit after the substrate is processed.

13. The substrate processing apparatus of claim 9, wherein the control unit is further configured to control the heat exchange unit such that a temperature of the fluid supplied from the fluid supply pipe to the process chamber measured by the first temperature measuring unit while the substrate is processed in the process chamber is equal to a temperature of the fluid supplied from the fluid supply pipe to the heat exchange unit after the substrate is processed.
